(19) United States
(12) Patent Application Publication
(10) Pub. No.: US 2012/0135353 A1
(43) Pub. Date: May 31, 2012

(54) FUNCTIONALLY GRADIENT INORGANIC RESIST, SUBSTRATE WITH FUNCTIONALLY GRADIENT INORGANIC RESIST, CYLINDRICAL BASE MATERIAL WITH FUNCTIONALLY GRADIENT INORGANIC RESIST, METHOD FOR FORMING FUNCTIONALLY GRADIENT INORGANIC RESIST AND METHOD FOR FORMING FINE PATTERN, AND INORGANIC RESIST AND METHOD FOR FORMING THE SAME

(75) Inventors: Isao Amemiya, Kai-City (JP); Sakae Nakatsuka, Hohito-City (JP); Kazutake Taniguchi, Hokuto-City (JP); Ikuru Kimura, Nirasaki-shi (JP)

(73) Assignee: HOYA CORPORATION, Tokyo (JP)

(21) Appl. No.: 13/381,232

(22) PCT Filed: Jul. 1, 2010
(86) PCT No.: PCT/JP2010/061259

§ 371 Date: Feb. 9, 2012

(30) Foreign Application Priority Data
Jul. 3, 2009 (JP) 2009-158671

(51) Int. Cl. G03F 7/20; G03F 7/075; G03F 7/004

(52) U.S. Cl. 430/289.1; 430/270.1; 430/325

(57) ABSTRACT

A functionally gradient inorganic resist that changes in its state by heat, having a main surface irradiated with laser beams and a rear surface opposed to the main surface; the functionally gradient inorganic resist including a single layer resist, wherein at least a composition of the single layer resist is continuously varied from the main surface side to the rear surface side, and anisotropy of an area in which a temperature reaches a fixed temperature when being irradiated with laser beams locally, is continuously increased from the main surface side to the rear surface side in the single layer resist.

### TECHNICAL FIELD

The present invention relates to a functionally gradient inorganic resist, a substrate with a functionally gradient inorganic resist, a cylindrical base material with a functionally gradient inorganic resist, a method for forming the functionally gradient inorganic resist and a method for forming a fine pattern thereon, and an inorganic resist and a method for manufacturing the same, and particularly relates to a functionally gradient inorganic resist on which a fine pattern is formed and which is made of a high resolution thermo-sensitive material, and a high precision nano-imprint mold using the same.

### DESCRIPTION OF RELATED ART

In recent years, applications requiring fine patterning of 100 nm or less, have been developed.

For example, in a magnetic recording field, as a next generation system of a perpendicular recording system, a technique called a discrete track media technique, namely a technique of forming a non-magnetic groove with a width of 30 nm to 40 nm at an interval of 100 nm to 150 nm, is known.

By using this technique, magnetic-noise in a horizontal direction can be reduced. Owing to this effect, further increase in recording density such as 500 GB (Giga Byte) or more is achieved.

Further, in a display field, a surface antireflection structure having a Moth Eye structure is known, in which fine dot patterns with a wavelength of ½ or less are regularly arranged.

Further, a wire grid type polarizer (polarizing plate) has been proposed as an alternative method for an optical polarizer (polarizing plate) based on a stretching method that has low production yield. A wire grid polarizer has a high reflectance material such as aluminum formed on an uneven surface of 50 nm to 200 nm.

Further, needs for fine patterning has been increased, in a field of a bio-sensing chip requiring a fine pillar structure and for improving external light extraction efficiency of a LED light source.

In the aforementioned fine processing, the technique of forming a fine pattern is generally performed based on a leading semiconductor lithography technique.

Meanwhile, a high precision processing is required for device manufacturing in which fine patterning is performed. In order to realize the highly precise processing, particularly in optical lithography, among various semiconductor lithography techniques, a light source, a resist material, and an exposure system, etc., have been comprehensively studied.

Note that in this optical lithography, as a design specification, a semiconductor device has a minimum design dimension of 90 nm to 65 nm. This dimension corresponds to ½ to ⅓ of 193 nm wavelength ArF excimer laser.

In order to form a pattern with not more than a wavelength of the light source as described above, it is necessary to apply a super-resolution technique such as a phase shift method, an oblique incident illumination method, and a pupil filter method, and an optical proximity correction (OPC) technique.

In addition, for the purpose of realizing a further finer pattern, an immersion technique has been investigated, which is a technique of filling a space between a projection lens and a wafer with liquid such as water, in a reflective EUV (Extreme Ultra Violet) reduction projection exposure technique using a soft X-ray having a wavelength of 13 nm, or an ArF exposure technique.

Thus, in the optical lithography, in order to realize a further finer pattern, further shorter wavelength of the light source is required, and the phase shift method and the OPC technique are required. In addition, the aforementioned immersion technique is being used now.

Note that as a semiconductor lithography method excluding the optical lithography, a charged particle beam drawing method employing electron beam and ion beam for the light source, is known. Such light sources are excellent in realizing a finer pattern, because the wavelength thereof is extremely shorter than the wavelength of light, and therefore are used for research and development mainly regarding a further finer pattern, such as a development of a leading-edge semiconductor.

Further, as other drawing or light exposure method, a two-photon light absorption method (or called a photon interference light exposure method) is known, which is a method for concentrating two lights by a lens so that a light intensity can be obtained to develop only a part where light is absorbed by two-photons.

Meanwhile, in contrast with the optical lithography, a heat reactive lithography (called a thermal lithography hereafter) is also developed, which is a lithography called a phase change lithography using laser beams as a heat source, and using an inorganic resist as a thermo-sensitive material (for example, see patent document 1).

This technique is mainly developed as a method for manufacturing a master disk for a Blue-Ray optical disk which is an optical recording technique that comes after (following) DVD, and in patent document 1, minimum pattern size is 130 nm to 140 nm.

The thermal lithography technique is also described as follows in other prior art document.

First, non-patent document 1 describes resolution of 90 nm dot (hole) pattern and 80 nm line pattern by the phase change lithography using tellurium oxide (TeOx).

Similarly, non-patent document 2 and non-patent document 3 describe a 100 nm dot pattern using inorganic platinum oxide (PtOx) as a thermo-sensitive material.

Further, patent document 2 and patent document 3 describe a method for forming a fine pattern utilizing a recrystallization rate, by using germanium/antimony/tellurium (GeSbTe:GST material) as resist materials.

Further, patent document 4 describes multiple layers of a resist layer with different compositions, while using the thermal lithography.

### PRIOR ART DOCUMENTS

### Patent Documents

### Patent Document 1:

Japanese Patent Laid Open Publication No. 2003-315988

### Patent Document 2:

Japanese Patent Laid Open Publication No. 2005-78738

### Patent Document 3:

Japanese Patent Laid Open Publication No. 2005-100526

### Patent Document 4:

International Patent publication No. WO2005/055224

### Non-Patent Document

Non-patent document 1: E. Ito, Y. Kawaguchi, M. Tomiyama, S. Abe and E. Ohno, Jpn. J. Appl. Phys. 44, 5B 3574 (2005)
Non-patent document 2: K. Kurihara, Y. Yamakawa, T. Shima, T. Nakano, M. Kuwahara, and J. Tominaga, Jpn. J. Appl. Phys. 45, 1379 (2006)
Non-patent document 3: K. Kurihara, Y. Yamakawa, T. Nakano, and J. Tominaga, J. Opt. A: Pure appl. Opt., 8 S139 (2006)

### SUMMARY OF THE INVENTION

### Problem to be Solved by the Invention

At present, in addition to semiconductor device such as DRAM (Dynamic Random Access Memory), in each field such as a magnetic device (magnetic media), a display device such as LCD (Liquid Crystal Display) and EL (Electro Luminescence), and an optical device such as an optical element, there is demand for the following;

(1) Fine pattern of 50 nm level on a planar substrate.

(2) Fine pattern on large area.

(3) Low cost fabrication of fine pattern.

Specific example of the above-mentioned demand is, a larger area for a display and circle-shaped fine concentric patterns on the entire surface of a magnetic disk.

However, an optical lithography method for manufacturing a semiconductor employs a technique based on a light exposure (drawing) in one device chip of several tens of mm level. Therefore, as is described in request (2), the optical lithography method is not suitable when a pattern formation area larger than a device size is required.

Further, in order to form a fine pattern of 50 nm or less as described in request (1), an application of a super-resolution technique such as a phase shift and an OPC technique is necessary, together with a use of a light source having a short wavelength. Therefore, manufacturing cost is continuously increasing, and accordingly the fine pattern of 50 nm or less is not viable for the purpose other than very high volume production of semiconductor, thus not satisfying request (3).

Note that regarding other method of optical lithography, a charged particle beam drawing method is excellent in forming a fine pattern however, it is poor in productivity and basically can't cope with a large area, and therefore is not suitable for the purpose of the present invention.

Further, a two-photon light absorption process is described as a method for forming a pattern other than the semiconductor lithography. This process is a technique of causing a non-linear phenomenon caused by two-photon excitation by simultaneously absorbing two-photons, and the same effect is obtained as the effect at the time of absorbing one photon having a half-wavelength. Namely, ½ of a use wavelength is a resolution limit, to thereby achieve a finer pattern.

Meanwhile, generation probability of the two-photon absorption is extremely low, and therefore high photon density is required. In addition, laser beam with high output of the light source needs to be concentrated by a short focus lens, for generating two-photon absorption inducement, thus resulting in increasing cost. Particularly, pattern formation performed on a cylindrical body having a curvature, involves a problem such as high cost and technical difficulty.

Further, since the resolution is ½ wavelength, even if an ArF excimer laser having a wavelength of 193 nm is used, the resolution limit is about 100 nm, which is regarded as being unsuitable.

Further, as far as conventional thermal lithography is concerned, resist resolution of 50 nm level as described below, can not be realized yet.

Further, in non-patent document 1, there is no report on reproducible fabrication of 50 nm level, which is required in a wire grid polarizer (polarizing plate), while the resolution is insufficient.

Further, according to non-patent document 1, resolution of a pattern size is set to 11 nm. However, this is not the resolution of a laser irradiation part, but the resolution of a part corresponding to a space between irradiation parts (gap between irradiation parts), and it can't be said that this is an original resolution characteristic.

Similarly, according to non-patent document 2 and non-patent document 3, platinum oxide is evaporated by a rapid sublimation reaction during decomposition in a temperature range of 550° C. to 600° C., wherein mainly oxygen is evaporated during decomposition, and it can be considered that platinum after decomposition is scattered around as metal or suboxide.

When the temperature of the platinum oxide rises to a prescribed point in the middle of irradiation, to thereby accelerate decomposition and change volume of the resist, focal deviation of the laser is caused, thus making it difficult to form a fine pattern on one layer.

Further, there is no versatility in controlling the finer pattern by recrystallization according to patent document 2 and patent document 3, and it is difficult to control dimensions of all patterns when formation of various sizes and various shapes is required on the same substrate.

Further, from a viewpoint of a chronological stability of the resist, a GST material is likely to be degraded, thus requiring a protective film to prevent such degradation. Therefore, the protective film needs to be formed before/after exposing (drawing) the resist, and also the protective film needs to be selectively removed. Further, from a viewpoint of lithography, the GST material has a problem in resistance to chemical washing for removing foreign matters, and therefore the GST material is of no practical use.

Further, patent document 4 describes a technique of using a mold with a resist layer formed on a substrate, as the mold for fabricating a master disk for an optical disk.

There is no direct relation between this technique and the present invention. Namely, this technique is simply a related technique having no direct relation with the present invention which is mainly applied to a technique of transferring a resist pattern to a substrate.

According to a first embodiment of the patent document 4, a resist layer is formed on a substrate 101, in a three-layer structure of a layer containing a low oxygen content (102c), a layer containing average oxygen content (102b), and a layer containing high oxygen content (102a) in an order from a main surface of a resist layer 102 toward a bottom surface of the resist layer (FIG. 18(b) as will be described later).

Regarding this case, according to the patent document 4, a resist pattern 103 is formed by increasing oxygen concentration from the main surface of the resist layer toward the bottom surface of the resist layer, thereby solving an insufficient development phenomenon in the vicinity of the bottom surface of the resist layer.

However, as shown in comparative example 2 as will be described later, there is a problem that the resolution satisfying the present request can't be obtained.

Meanwhile, according to a second embodiment of the patent document 4, a resist layer is formed on the substrate 101, in a three-layer structure of a layer containing high oxygen content (102c), a layer containing average oxygen content (102b), and a layer containing low oxygen content (102a) in an order from the main surface of the resist layer toward the bottom surface of the resist layer (FIG. 18(c) as will be described later).

In this case, the bottom surface of the resist layer has a low sensitivity, thus involving a problem that insufficient development phenomenon occurs. As a result, a fine resist pattern 103 can't be formed, and therefore there is a possibility that the aforementioned criteria (1) is not satisfied.

Regarding formation of the fine pattern in a large area at a low cost, it can also be considered that a roll nano imprint method is used, which is a method of transferring a pattern on the surface of the mold to a workpiece, by bringing a cylindrical roller mold into rolling contact with the surface of the workpiece.

However, in a conventional roll nano imprint method, a fine pattern of 100 nm or less can't be formed directly on the surface of a drum.

Further, conventionally pattern formation is performed on a roller mold by applying nickel (Ni) electro forming plating to a master plate (original plate) which is fabricated using a semiconductor lithography method, thereby fabricating a flexible nickel mold, and the nickel mold thus fabricated is wound around a base material.

However, this pattern formation technique has a problem that the mold size is limited to an area formed by the semiconductor lithography, and a continuous pattern without break can't be formed on a long body because a flat plate is wound around the base material.

An object of the present invention is to improve the resolution of the resist in case of the thermal lithography using a focused laser, thus making it possible to form a fine pattern in a large area at a low cost.

### Means for Solving the Problem

According to a first aspect of the present invention, there is provided a functionally gradient inorganic resist that changes in its state by heat, having:

a main surface irradiated with laser beams and a rear surface opposed to the main surface;

the functionally gradient inorganic resist including a single layer resist,

wherein at least a composition of the single layer resist is continuously varied from the main surface side to the rear surface side, and

anisotropy of an area in which a temperature reaches a fixed temperature when being irradiated with laser beams locally, is continuously increased from the main surface side to the rear surface side in the single layer resist.

According to a second aspect of the present invention, there is provided a functionally gradient inorganic resist that changes in its state by heat, having:

a main surface irradiated with laser beams and a rear surface opposed to the main surface,

the functionally gradient inorganic resist including a single layer resist,

wherein in this single layer resist, a resist resolution characteristic value of the single layer resist is continuously varied from the main surface side to the rear surface side, and anisotropy of an area in which a temperature reaches a fixed temperature when being irradiated with laser beams locally, is continuously increased from the main surface side to the rear surface side,

wherein the resist resolution characteristic value is a physical value of a resist having an influence on a resolution of the resist.

According to a third aspect of the present invention, there is provided a functionally gradient inorganic resist according to the second aspect, wherein the resist resolution characteristic value is one or two or more values selected from optical-absorption coefficient, thermal conductivity, and resist sensitivity, wherein, the resist sensitivity is a characteristic defined by a dimension of a portion that can be developed when the resist is irradiated with laser beams having a prescribed dimension and irradiation amount.

According to a fourth aspect of the present invention, there is provided a functionally gradient inorganic resist according to any one of the first to third aspects, wherein the single layer resist is made of a combination of at least one or more elements selected from Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and oxygen and/or nitrogen, and a composition ratio of the selected element and oxygen and/or nitrogen is continuously varied from the main surface side to the rear surface side.

According to a fifth aspect of the present invention, there is provided a functionally gradient inorganic resist according to any one of the first to third aspects, wherein the single layer resist is made of a first material composed of at least one of suboxide, nitride, or suboxynitride of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and a second material made of at least one of the above elements excluding the first material, wherein compositions of the first material and the second material are relatively and continuously varied from the main surface side to the rear surface side.

According to a sixth aspect of the present invention, there is provided a functionally gradient inorganic resist of a single layer that changes in its state by heat, having:

a main surface irradiated with laser beams and a rear surface opposed to the main surface,

wherein the single layer resist is made of a combination of at least one or more elements selected from Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and oxygen and/or nitrogen, and

a composition ratio of the oxygen and/or the nitrogen with respect to the selected element is continuously smaller from the main surface side to the rear surface side in a range of a composition ratio or more of the oxygen and/or the nitrogen allowing a resist sensitivity to show a maximum value in a relation between the composition ratio of the oxygen and/or the nitrogen with respect to the selected element, and the resist sensitivity, and

anisotropy of an area in which a temperature reaches a fixed temperature when being irradiated with laser beams locally, is continuously increased from the main surface side to the rear surface side.

According to a seventh aspect of the present invention, there is provided a functionally gradient inorganic resist according to the sixth aspect, wherein the material of the single layer resist is a substance expressed by WOₓ (0.4≦x≦2.0), and a value of x is continuously decreased from the main surface side to the rear surface side.

According to an eighth aspect of the present invention, there is provided a functionally gradient inorganic resist according to any one of the first to seventh aspects, wherein a thickness of the single layer resist is in a range of 5 nm or more and less than 40 nm.

According to a ninth aspect of the present invention, there is provided a functionally gradient inorganic resist according to anyone of the first to eighth aspects, wherein the single layer resist has an amorphous structure in which optical characteristic and thermal characteristic are varied in a gradient manner from the main surface side to the rear surface side,

wherein, the optical characteristic includes optical-absorption coefficient, and is the characteristic caused by light, having an influence on the resolution of the resist, and the thermal characteristic includes thermal conductivity, and is the characteristic caused by light, having an influence on the resolution of the resist.

According to a tenth aspect of the present invention, there is provided a substrate with a functionally gradient inorganic resist including a ground layer made of a material different from the materials of the functionally gradient inorganic resist and the functionally gradient inorganic resist according to any one of the first to ninth aspects,

wherein the material of the ground layer is

(1) at least one or more of oxides, nitrides, carbides of Al, Si, Ti, Cr, Zr, Nb, Ni, Hf, Ta, and W, or a composite compound of them, or

(2) (i) at least one or more of amorphous carbon, diamond-like carbon, graphite comprising carbon, or carbide nitride comprising carbon and nitrogen, or

(ii) at least one or more of materials obtained by doping a carbon-containing material with fluorine.

According to an eleventh aspect of the present invention, there is provided a functionally gradient inorganic resist according to the tenth aspect, wherein a thickness of the ground layer is in a range of 10 nm or more and less than 500 nm.

According to a twelfth aspect of the present invention, there is provided a substrate with a functionally gradient inorganic resist, comprising:

an etching mask layer formed under the functionally gradient inorganic resist of any one of claims 1 to 9; and

the ground layer formed under the etching mask layer,

wherein a material of the etching mask layer is

(1) at least one or more of Al, Si, Ti, Cr, Nb, Ni, Hf, and Ta, or a compound of them, or

(2) (i) at least one or more of amorphous carbon, diamond-like carbon, graphite comprising carbon, or carbide nitride comprising carbon and nitrogen, or

(ii) at least one or more of materials obtained by doping a carbon-containing material with fluorine.

According to a thirteenth aspect of the present invention, there is provided the substrate with functionally gradient inorganic resist according to the twelfth aspect, wherein a thickness of the etching mask layer is in a range of 5 nm or more and less than 500 nm.

According to a fourteenth aspect of the present invention, there is provided the substrate with a functionally gradient inorganic resist, wherein the substrate is mainly composed of metal, alloy, quartz glass, multi-component glass, crystal silicon, amorphous silicon, glasslike carbon, glassy carbon, and ceramics.

According to a fifteenth aspect of the present invention, there is provided a cylindrical base material with a functionally gradient inorganic resist, wherein the cylindrical base material is used instead of the substrate of any one of the tenth to fourteenth aspects.

According to a sixteenth aspect of the present invention, there is provided a method for forming a functionally gradient inorganic resist which changes in its state by heat

having a main surface irradiated with laser beams and a rear surface opposed to the main surface,

wherein at least one single layer resist constituting the resist is composed of a combination of at least one or more elements of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, Bi, and oxygen and/or nitrogen,

wherein at least a composition of the single layer resist is continuously varied from the main surface side to the rear surface side, by continuously varying at least one of gas partial pressure, film forming rate, and film forming output for forming the single layer resist.

According to a seventeenth aspect of the present invention, there is provided a method for forming a fine pattern, comprising:

applying drawing or exposure to a substrate on which the functionally gradient inorganic resist of any one of claims 1 to 9 is formed, by focused laser beams;

forming a portion that changes in its state locally on the resist; and

causing selective dissolution to occur by development.

According to an eighteenth aspect of the present invention, there is provided an inorganic resist that changes in its state, having:

a main surface irradiated with laser beams and a rear surface opposed to the main surface,

wherein the rear surface side of the inorganic resist has a composition allowing a resist sensitivity to show a maximum value in a relation between a composition of the inorganic resist and the resist sensitivity.

According to a nineteenth aspect of the present invention, there is provided a method for forming an inorganic resist that changes in its state, having amain surface irradiated with laser beams and a rear surface opposed to the main surface,

the method comprising:

obtaining a composition allowing a resist sensitivity to show a maximum value in a relation between a composition of the inorganic resist and the resist sensitivity; and

forming an inorganic resist so that the rear surface side of the inorganic resist has a composition allowing the resist sensitivity to show the maximum value.

### Advantage of the Invention

According to the present invention, resist resolution at the time of thermal lithography using focused laser beam can be improved, and a fine pattern can be formed in a large area at a low cost.

### BRIEF DESCRIPTION OF THE DRAWINGS

FIG. 1 is a view showing a relation between optical-absorption coefficient of resist and oxygen concentration (x) in an inorganic resist when a material composition is defined as WOx.

FIG. 2 is a view showing a relation between thermal conductivity of resist and oxygen concentration (x) in an inorganic resist when a material composition is defined as WOx.

FIG. 3 is a view showing a relation between a resolution pattern dimension and oxygen concentration (x) in an inorganic resist when a material composition is defined as WOx.

FIG. 4 is a schematic view for describing anisotropy and isotropy of a temperature distribution when the resist is irradiated with focused laser beams.

FIG. 5 is a schematic view showing a process of forming a pattern by etching process on a ground base material (base substrate) using inorganic resist as an etching mask.

FIG. 6 is a schematic view showing a process of forming a pattern by an etching process on an inorganic resist/a ground layer/a base material (substrate) in an order from a resist main surface toward a resist rear surface.

FIG. 7 is a schematic view showing a process of forming a pattern by an etching process on an inorganic resist/an etching mask layer/a ground layer/a base material (substrate) in an order from the resist main surface toward the resist rear surface.

FIG. 8 is a scanning electron microscope photograph showing a fine pattern formation result using functionally gradient high resolution inorganic resist (observed from above) according to an example 1 of the present invention.

FIG. 9 is a scanning electron microscope photograph showing a fine pattern formation result (observed in a cross-section) using the functionally gradient high resolution inorganic resist according to an example 1 of the present invention.

FIG. 10 is a scanning electron microscope photograph showing a fine patter formation result (observed from above) using an oxygen-deficit type single layer inorganic resist.

FIG. 11 is a scanning electron microscope photograph showing a fine pattern formation result (observed in a cross-section) using the oxygen-deficit type single layer inorganic resist.

FIG. 12 is a scanning electron microscope photograph showing a fine pattern formation result (observed from above) using inorganic resist having an oxygen compositionally gradient structure (sample A) according to comparative example 2.

FIG. 13 is a scanning electron microscope photograph showing fine pattern formation result (observed from above) using inorganic resist having an oxygen compositionally gradient structure (sample B) according to comparative example 2.

FIG. 14 is a scanning electron microscope photograph showing a fine pattern formation result (observed in a cross-section) using inorganic resist having the oxygen compositionally gradient structure (sample A) according to comparative example 2.

FIG. 15 is a scanning electron microscope photograph showing a result of forming a fine pattern (observed from above) on a SiO₂ ground layer according to example 2 of the present invention.

FIG. 16 is a scanning electron microscope photograph showing a result of evaluating a cross-section of a sample in which etching process is applied to a substrate after the functionally gradient inorganic resist and an etching mask of the present invention are formed on a quartz wafer.

FIG. 17 is a scanning electron microscope photograph showing a result of evaluating a cross-section after an already used etching mask is selectively removed, regarding the sample of FIG. 16.

FIG. 18 is a cross-sectional schematic view of inorganic resist and a base material (substrate) having a pattern, wherein (a) shows an embodiment of the present invention, (b) shows a first embodiment of patent document 4, and (c) shows a schematic view of a second embodiment of the patent document 4, while showing a relation between degree of oxidation and sensitivity.

FIG. 19 is a view showing a relation between a resolution pattern dimension and sputtering oxygen concentration when a material composition is defined as WOx.

FIG. 20 is a view showing a relation between density and the sputtering oxygen concentration when the material composition is defined as WOx.

### DETAILED DESCRIPTION OF THE INVENTION

As described above, inventors of the present invention examines the aforementioned three points with strenuous efforts, which are required for inorganic resist at present, namely,

(1) formation of a fine pattern of 50 nm level in a case of a planar substrate (formation of a fine pattern of 100 nm level in a case of a cylindrical base material),

(2) formation of the fine pattern in a large area, and

(3) formation of the fine pattern at a low cost.

At this time, the inventors of the present invention pay attention to a temperature distribution in the inorganic resist.

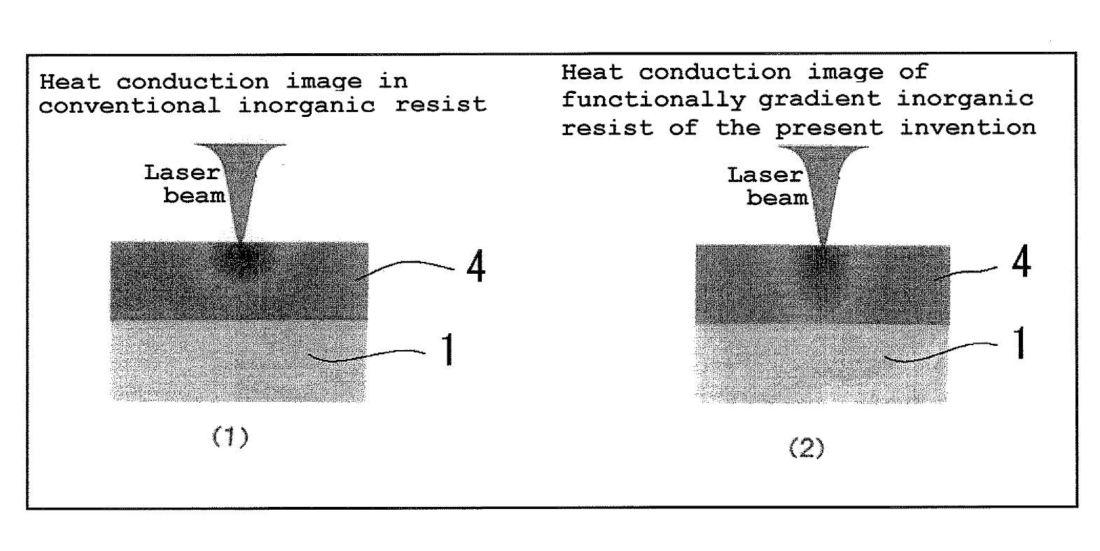

Usually, when inorganic resist 4 made of a material containing a uniform composition and a uniform density, is irradiated with laser beams locally, the temperature distribution of the inorganic resist 4 shows an isotropic distribution with an irradiation part at the center (FIG. 4(1)).

Even if one resist having multilayer resist is formed as described in patent document 4, the temperature distribution shows the isotropic distribution in each resist layer as a result.

When the temperature distribution of a resist layer shows isotropic distribution, a boundary between an exposed portion and a non-exposed portion is not formed clearly. As a result, resolution during development is degraded.

Therefore, in order to improve the resolution of the fine pattern, the inventors of the present invention examine a technique of having not the isotropic temperature distribution as conventional, but an anisotropic temperature distribution, in a phase change lithography using laser drawing or light exposure.

In such an examination, in order to form a single layer inorganic resist WOx on different substrates which are not compositionally varied in a gradient manner in a depth direction of a film, the inventors of the present invention set a constant sputter concentration of oxygen to be varied corresponding to each substrate. Specifically, the inorganic resist was formed by setting constant oxygen concentration to 10%, 15%, 25%, and 30%.

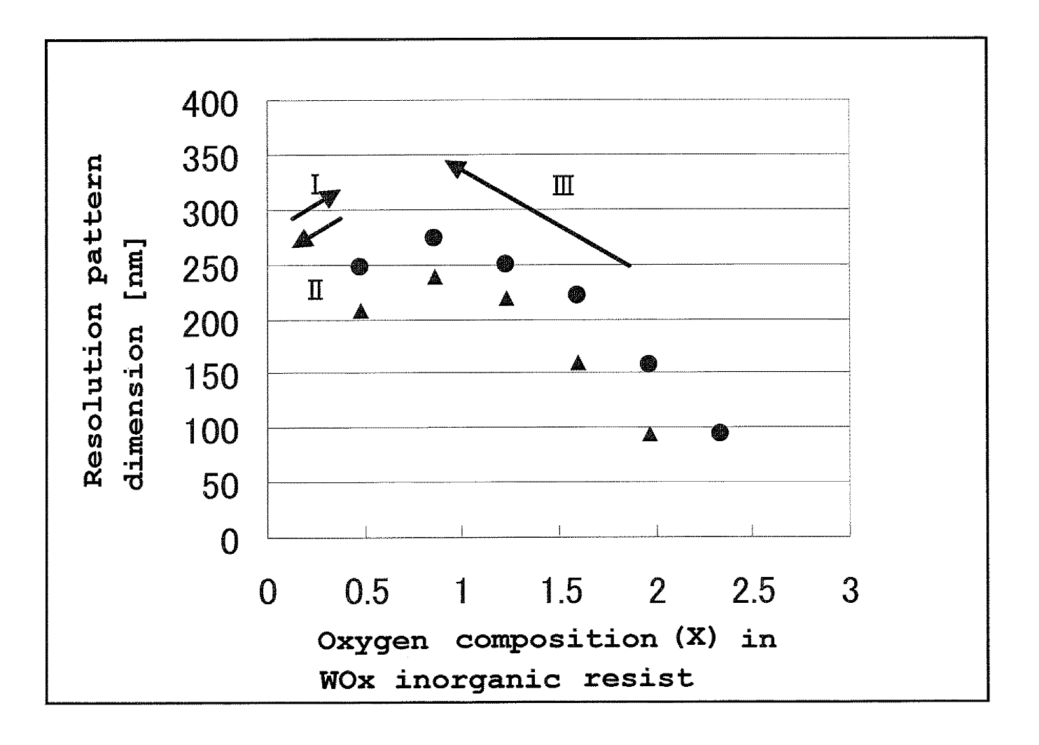

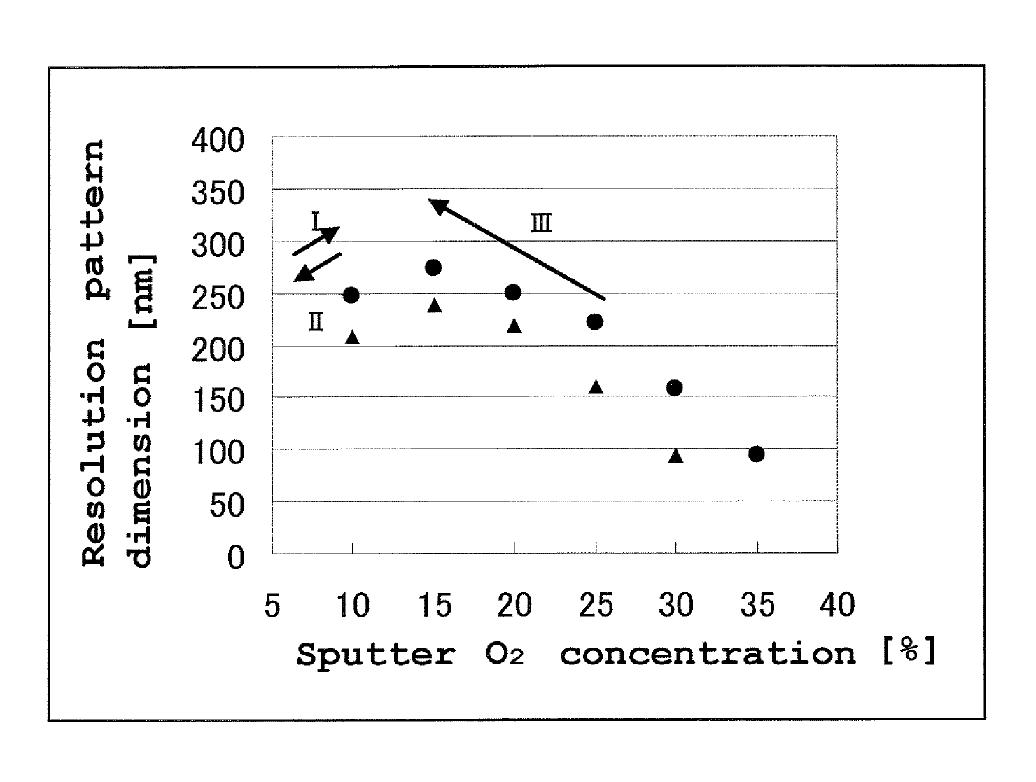

Then, these samples were exposed to light under same laser irradiation conditions (constant irradiation area and constant irradiation amount: two conditions shown by and ▴ in FIG. 3 and FIG. 19), to thereby examine sensitivity of the inorganic resist. A result thereof is shown in FIG. 19.

Wherein specific conditions of ▴ are as follows.

The resist with a film thickness of 20 nm was irradiated with laser beams in a bit pattern (diameter: 400 nm) under both conditions of and ▴. Then, the resist film was developed by a developer (TMAH: 2.38%) at a normal temperature (about 20° C.). Laser output was set to 24 mW as a condition of , and laser output was set to 21 mW as a condition of ▴.

In addition, as shown in FIG. 19, a sample was prepared in which an inorganic resist WOx layer of a single layer (wherein X is 0.485, 0.856, 1.227, 1.598, 1.969, 2.34) was formed on a separate substrate respectively with no compositional gradient in a depth direction of the film, and these samples were exposed to light under the same laser irradiation conditions similarly to FIG. 19, (constant irradiation area and constant irradiation amount: which are two conditions shown by and ▴ in FIG. 3 and FIG. 19), to thereby examine the sensitivity of the inorganic resist. Results thereof are shown in FIG. 3.

Note that the “sensitivity” is defined by a dimension of a portion that can be developed when the resist is irradiated with laser beams having a prescribed dimension. The dimension or the sensitivity of the resist is also called hereafter “a resolution pattern dimension” after development of the inorganic resist.

As shown in FIG. 3, it was found that the resolution pattern dimension (the sensitivity of the resist) was not increased monotonously (rising to the right), as the oxygen concentration was increased, and a maximum value was set at a point where the sensitivity of the resist was maximum.

Namely, as is described in patent document 4, it was found that the sensitivity of the resist was not increased as the oxygen concentration was higher, and the sensitivity defined by the resolution pattern dimension was highest at the point of the aforementioned maximum value.

Based on the aforementioned knowledge, the inventors of the present invention achieves a concept that a single layer resist is provided extending from the main surface of the resist irradiated with laser beams first, to the rear surface of the resist, so that at least the composition of the resist is continuously varied (the sensitivity of the resist is continuously varied toward the aforementioned maximum value), and the anisotropy of an area in which a temperature is fixed, is continuously increased toward the rear surface side from the main surface side.

With this structure, the anisotropy of the area in which temperature is fixed, is continuously increased, toward the rear surface side (namely, toward the depth direction of the resist) from the main surface side of the resist. As a result, it is found that the present invention can cope with a larger area and a low cost and also can obtain high resolution.

A direction from the main surface of the resist irradiated with laser beams first toward the rear surface of the resist, is also called a “depth direction of the resist”.

Further, as shown in FIG. 4(2), the “anisotropy of the area in which the temperature is fixed” means that an extension of the fixed temperature region in the depth direction is larger than an extension in the horizontal direction.

Then, the “anisotropy is continuously increased” means that in the distribution (light absorbing distribution) in which the temperature reaches a fixed temperature, the extension of the fixed temperature region in the depth direction is continuously increased toward the rear surface side of the resist, more than the extension of the resist in the horizontal direction as shown in FIG. 4(2), even if the extension of the fixed temperature region in the horizontal direction and the extension of the fixed temperature region in the depth direction are equal to each other (isotropic) on the main surface side of the resist as shown in FIG. 4(1).

### Embodiment 1

An embodiment of the present invention will be described hereafter.

The embodiment of the present invention will be described in the following order.

1. Outline of the functionally gradient inorganic resist
2. Details of the functionally gradient inorganic resist

1) Composition

2) Resist resolution characteristic value

i) Prediction of resist composition for the present invention from the correlation of a resist resolution characteristic and resist composition

ii) Resist sensitivity

iii) Optical characteristic (optical-absorption coefficient)

iv) Thermal characteristic (thermal conductivity)

3) Film thickness

4) Structure

3. Outline of a substrate with functionally gradient inorganic resist
4. Details of a substrate with functionally gradient inorganic resist

1) Substrate (base material)

2) Ground layer

3) Etching mask layer

4) Inorganic resist

5. A method for manufacturing the substrate with functionally gradient inorganic resist

1) Formation of the functionally gradient inorganic resist

2) Formation of a fine pattern on the resist

3) Formation of the fine pattern on the substrate

6. Explanation for an effect of this embodiment

<1. Outline of the Functionally Gradient Inorganic Resist>

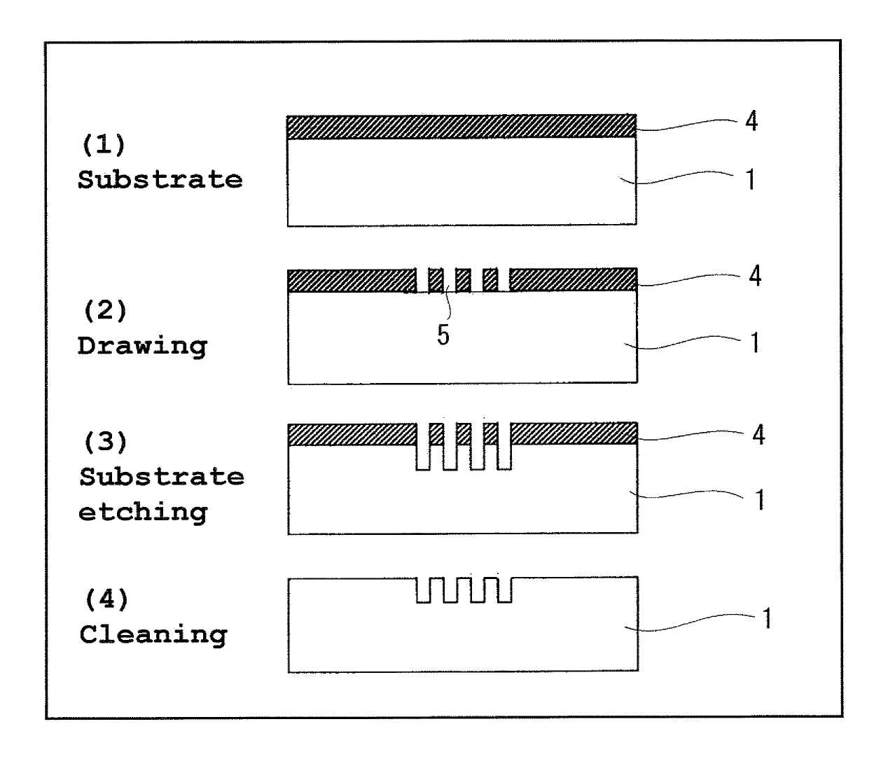

FIG. 5(1) is a schematic sectional view showing the functionally gradient inorganic resist according to an embodiment of the present invention. The “functionally gradient inorganic resist” is simply called an “inorganic resist” hereafter.

Further, the “functionally gradient” means that a characteristic of a resist such as thermal conductivity, refractive index, and optical-absorption coefficient, is varied continuously in the depth direction of the resist, by continuously varying the composition ratio, density, and degree of oxidation in the depth direction of the resist in a gradient manner.

By continuously varying each function in the depth direction of the inorganic resist (namely functional variation in a gradient manner), “increase of the temperature distribution anisotropy”, “increase of the thermal anisotropy in an area where phase change occurs”, or “increase of heat conduction anisotropy” can be achieved. Owing to this effect, the resist resolution upon thermal lithography using a focused laser can be improved.

The inorganic resist 4 of this embodiment is a single layer resist that changes its state by heat. In addition, the single layer resist has the main surface irradiated with laser beams for carrying out drawing or exposure, and the rear surface opposed to the main surface.

Note that the “single layer resist” in this embodiment refers to the resist formed under a resist forming condition such as a film forming period starting from a certain condition until the condition is non-continuously varied. Further, the expression “continuously” used in this embodiment, means that for example the resist film forming condition and the anisotropy, etc., of the area in which the temperature reaches a fixed temperature, are constantly varied, and means as it were, not an intermittent variation such as varying the condition or setting the condition to be fixed, but a constant variation such as constantly varying the condition in a continuous function so that a partial pressure of prescribed gas is monotonically increased or decreased, or the composition, etc., is monotonically increased or decreased during film formation.

Specifically, the resist formed immediately before varying the film forming condition to another condition is defined as the “single layer resist”, which is the resist formed by starting the film formation under a certain film forming condition, and continuing the film formation while constantly varying the film forming condition continuously (example: oxygen partial pressure is constantly gradually increased, thereby increasing the oxygen content on the main surface side of the resist) and non-continuously varying the condition to another film forming condition.

Meanwhile, the resist is formed by starting the resist forming condition under a certain film forming condition, and continuing the film formation while maintaining the condition, and thereafter non-continuously varying the condition to another film forming condition, in such a way that the resist is formed under another film forming condition. The resist thus formed is not included in the “single layer resist whose composition and resist resolution characteristic value are continuously varied”.

Based on this fact, the inorganic resist 4 of this embodiment includes the single layer resist with the composition of the inorganic resist 4 continuously varied from the main surface side to the rear surface side. Further, in this single layer resist, the anisotropy is increased from the main surface to the rear surface, in the area where the temperature reaches a fixed temperature when the inorganic resist 4 is locally irradiated with the laser beams.

<2. Details of the Functionally Gradient Inorganic Resist>

1) Composition

The material of the single layer resist is composed of a combination of an element selected from one or more of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and oxygen and/or nitrogen, and a composition ratio of the selected element and the oxygen and/or the nitrogen is preferably varied continuously from the main surface side to the rear surface side.

In this embodiment, by continuously varying the composition ratio of the selected element, with respect to any one of the group of oxygen, oxygen and nitrogen, and nitrogen, the resist resolution characteristic value (as will be described later) having a function of improving the resolution of the resist can be continuously varied (namely, varied in a gradient manner) from the main surface side to the rear surface side of the resist. Thus, the resolution of the resist upon thermal lithography using the focused laser beams can be improved.

Note that in this embodiment, the resist resolution characteristic value is continuously varied by continuously varying the composition ratio. However, the material of the inorganic resist may also be made of a substance whose compositional variation and variation of the resist resolution characteristic value are set in an independent or semi-independent relation.

Note that in this embodiment, the “resolution (resolution performance) of the resist is improved” means that a resolution limit of the resist is improved by varying the composition, etc., of the inorganic resist in the depth direction of the resist in a gradient manner depending on a purpose of use, regarding the resolution limit of a uniform single layer inorganic resist without functionally gradient variation.

In this embodiment, the inorganic resist 4 will be described using tungsten (W) and oxygen (O) as an example.

Note that the density in the single layer resist may also be continuously varied from the main surface side to the rear surface side, similarly to the composition.

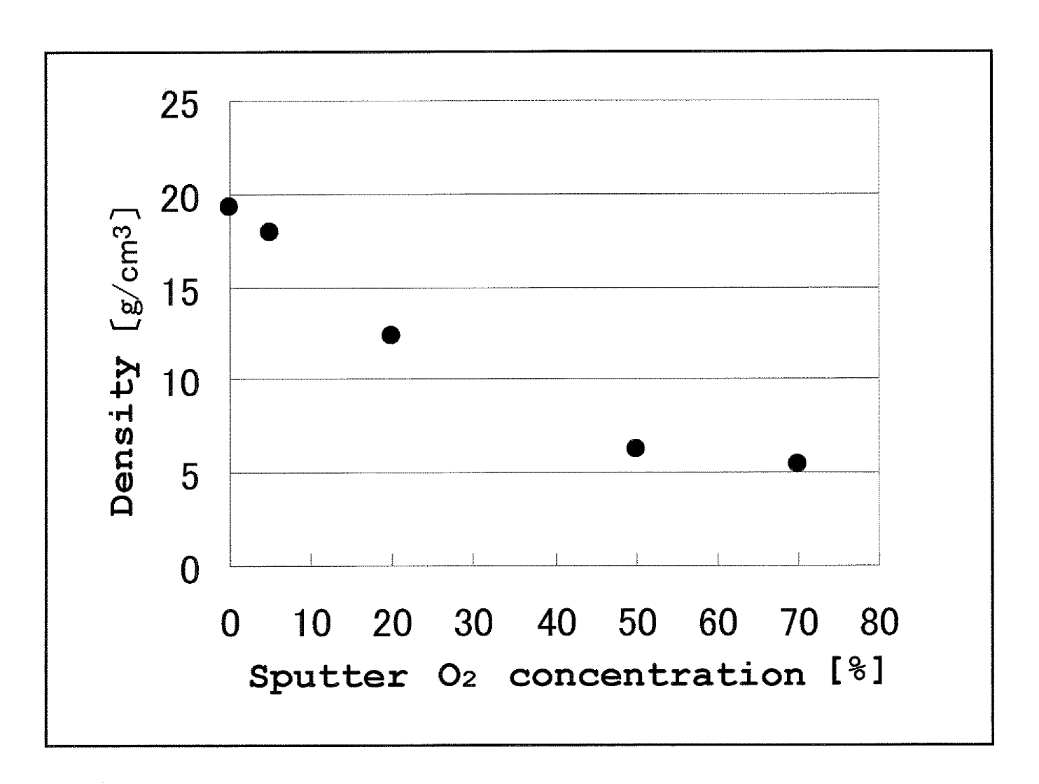

Regarding the variation of density, similarly to FIG. 3 and FIG. 19, FIG. 20 shows a relation between the density and a sputter concentration of oxygen. Namely, the density may be continuously varied from the main surface side to the rear surface side in an area where the density is varied simultaneously with varying the sputter concentration of oxygen. Specifically, the density may be continuously increased as shown in FIG. 20, because an oxygen ratio needs to be decreased from the main surface side to the rear surface side.

2) Resist Resolution Characteristic Value

Next, the resist resolution characteristic value of the inorganic resist 4 will be described. According to this embodiment, in the single layer resist, the resist resolution characteristic value is continuously varied from the main surface to the rear surface similarly to the composition.

The resist resolution characteristic value indicates a value of a physical property of the resist which has an influence on the resolution of the resist. Specifically, this is a value showing the resolution of the resist, more specifically, at least one of the “optical characteristic”, “thermal characteristic”, and “resist sensitivity” that have an influence on the anisotropy of the area where the temperature is fixed.

As a specific example, the optical-absorption coefficient and the refractive index can be given as the optical characteristic, and the thermal conductivity and specific heat can be given as the thermal characteristic.

Note that the resolution in this embodiment indicates a dimension capable of resolving a part irradiated with the laser beams. The dimension of a part not irradiated with the laser beams between laser irradiation parts (non-irradiated part) is excluded, because an essential resolution can't be carried out in such a part.

i) A Sequence Resulting in Focusing on a Resist Resolution Characteristic Value Based on the Resist Composition

A sequence resulting in focusing on a resist resolution characteristic value based on the resist composition, will be described before the optical characteristic, thermal characteristic, and the resist sensitivity are described in detail.

As described above, it is found by the inventors of the present invention, that the resolution pattern dimension (sensitivity of the resist) is not monotonously increased (rising to the right), with the increase of the oxygen concentration, but has a maximum value at a point where the resist sensitivity is highest (FIG. 3).

The inventors of the present invention consider the reason for allowing such a phenomenon to occur. Then, the inventors of the present invention examine the following matter.

First, the inventors of the present invention examine a relation between the oxygen concentration (x) in the inorganic resist 4 and the physical property (thermal conductivity, optical-absorption coefficient, refractive index, and specific heat, etc.) of the resist, when a material composition is defined as WOx.

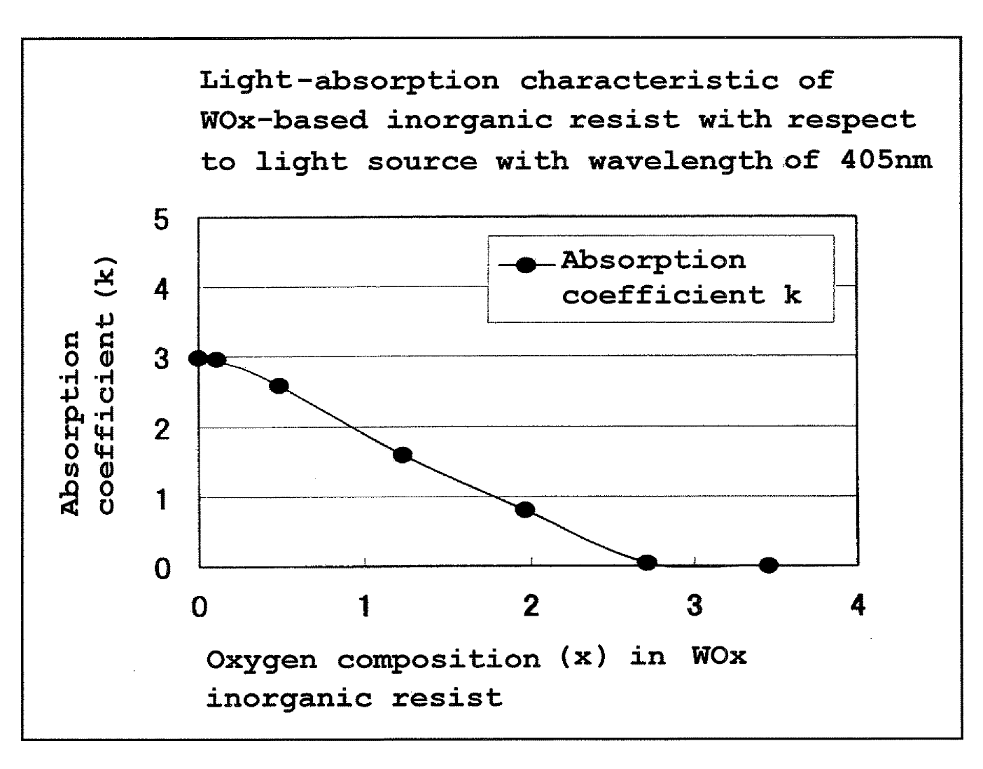

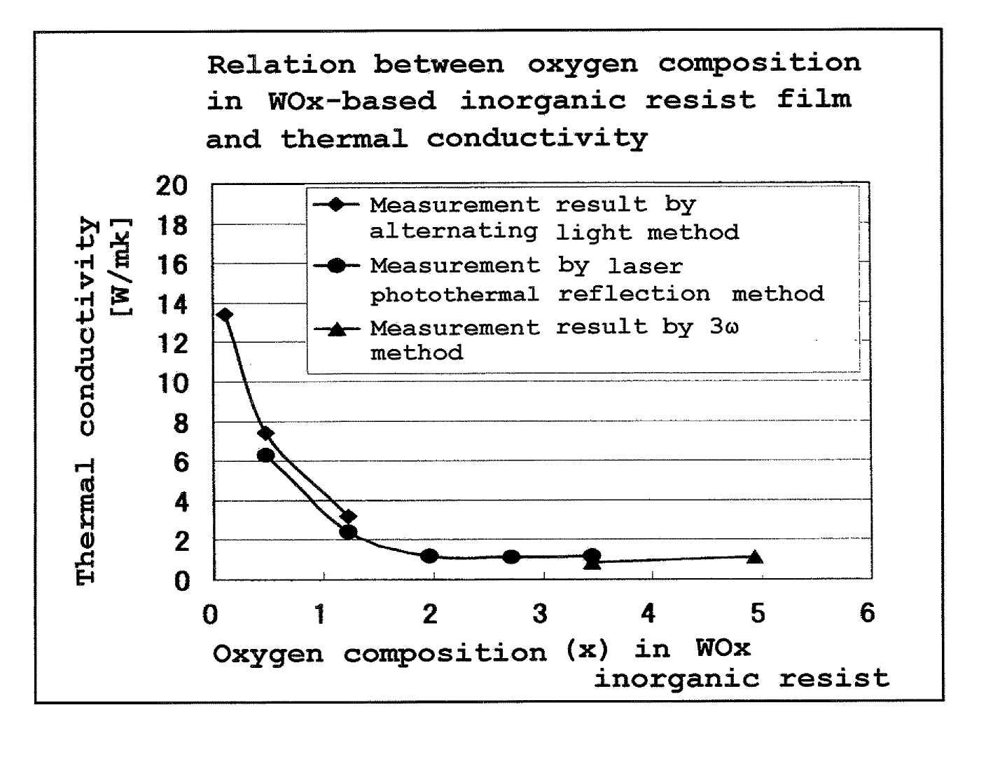

As a result, it is found that although the specific heat and the refractive index are not varied so much even if the value of x is varied, variations of the optical-absorption coefficient and the thermal conductivity are large according to the variation of the value of x (see FIG. 1 and FIG. 2).

First, from the relation between the thermal conductivity (FIG. 2) and the resolution pattern dimension (resist sensitivity) (FIG. 3), the following matter can be considered.

Namely, when only the thermal conductivity of the inorganic resist 4 is taken into consideration, increase of the thermal conductivity on the surface side is considered to be preferable from a viewpoint of conducting heat toward the rear surface side.

Meanwhile, decrease of the thermal conductivity on the rear surface side is considered to be preferable from a viewpoint of locally raising the temperature of the resist to a phase change temperature.

However, when a result of FIG. 3 is referenced, the relation between the resist sensitivity and the thermal conductivity shows a state different from a conventional estimation. Namely, it is found that the resist sensitivity is not necessarily improved because the thermal conductivity becomes small (namely, the value of x becomes large).

When the thermal lithography that carries out in this embodiment, is taken into consideration, it would be natural to consider that the variation of the thermal conductivity in the depth direction of the resist has a large influence on the resolution.

However, it is not necessarily appropriate to improve the resolution as described above by focusing on the variation of the thermal conductivity.

Meanwhile, the following matter can be considered from the relation between the optical-absorption coefficient (FIG. 1) having a large influence on the resolution, and the resolution pattern dimension (resist sensitivity) (FIG. 3).

Namely, regarding the optical-absorption coefficient, absorption heat quantity on the rear surface side is increased, by increasing the optical-absorption coefficient from the main surface side to the rear surface side of the resist. Therefore, it can be considered that there is an action effect of increasing the anisotropy toward the rear surface side.

As described above, from an examination result of FIG. 1 to FIG. 3, it is found by the inventors of the present invention, that the resolution limit is not determined only by a single characteristic (parameter), but is determined by a plurality of characteristics such as optical characteristic, thermal characteristic, and resist sensitivity.

Particularly, in the material composition satisfying x≦2.5 in a resist system (WOx) of this embodiment, it is found that an “overall heat conducting characteristic” determined by the plurality of characteristics is mainly influenced by the “optical-absorption coefficient”, although depending on the kind of the substrate 1.

Namely, in a suboxide resist system, it is found that “the anisotropy of the area where the temperature is fixed in the resist” can be obtained by determining a film composition by using mainly the “optical-absorption coefficient”. More specifically, in the suboxide resist system, the optical-absorption coefficient is preferably varied to be larger from the main surface side to the rear surface side of the resist.

Thus, in order to form a pattern having a fine and excellent sectional shape, it is found that the anisotropy of the area where the temperature reaches a fixed temperature, is increased toward the rear surface side, by designing a material so that a phase change temperature area is smaller as much as possible on the main surface side of the resist and heat can be easily absorbed toward the rear surface side, and as a result, the resolution of the resist is improved.

As shown in FIG. 4 showing the anisotropy of the area where the temperature reaches a fixed temperature, in a conventional uniform single layer inorganic resist 4 without functional variation in a gradient manner, the temperature distribution is isotropic when the resist is irradiated with the focused laser beams (FIG. 4(1)).

Meanwhile, in this embodiment (FIG. 4(2)), for example, by varying the characteristics such as sensitivity defined by the optical-absorption coefficient, thermal conductivity, and resolution pattern toward the depth direction of the resist, the anisotropy of the temperature distribution can be increased when the resist is irradiated with the focused laser beams.

Based on the aforementioned knowledge, the characteristics having an influence on the resolution of the resist, namely the anisotropy of the area where the temperature is fixed, will be specifically described individually.

ii) Resist Sensitivity

As is already described regarding the resist sensitivity, the resist sensitivity is a characteristic preferable to be used together with the optical-absorption coefficient and the thermal conductivity, and therefore explanation will be given again.

The “resist sensitivity” shown in FIG. 3 of this embodiment means the characteristic defined by the dimension of a developable portion when the resist is irradiated with the laser beams having a prescribed dimension and an irradiation amount.

Namely, when the resist is irradiated with the laser beams having the prescribed dimension and the irradiation amount, a major portion of the resist close to a laser dimension can be developed in a case of the resist with high resist sensitivity.

Reversely, in a case of the resist with low resist sensitivity, the resist is hardly exposed to light because the sensitivity is low, and only a smaller portion of the resist than the laser dimension can be developed.

Further, in a WOx-based inorganic resist 4, the resist sensitivity is preferably continuously increased in the depth direction of the resist so that a low resist sensitivity area is positioned on the main surface, and a high resist sensitivity area is positioned on the rear surface.

Specifically, the value of x is preferably varied toward the maximum value of FIG. 3 (the value of x where the resolution pattern dimension becomes maximum) from the main surface side to the rear surface side of the single layer resist.

Oxygen amount (x) may be selected in a range of x=2.5 on the main surface side of the resist, and x=0.856 on the rear surface side of the resist (interface side of a quartz substrate 1), when the material composition is defined as WOx.

Meanwhile, in this case, x is continuously increased toward the depth direction of the resist, namely toward the maximum value of the resist sensitivity in a graph showing the relation between the composition ratio of oxygen and/or nitrogen in the inorganic resist, and the resist sensitivity.

In this case, as shown by arrow III of FIG. 3, x is preferably continuously decreased toward the depth direction of the resist, in a range not less than the composition ratio of oxygen and/or nitrogen at a point where the resist sensitivity shows the maximum value, when the relation between the thermal conductivity (FIG. 2) and the optical-absorption coefficient (FIG. 1) is taken into consideration.

When the aforementioned matter is described in a case of WOx, x may be continuously increased toward the depth direction of the resist in a range of x≦0.856, and x is preferably continuously decreased toward the depth direction of the resist in a range of 0.856≦x≦2.5. This is because the variation is not excessively large, in the range of 0.856≦x≦2.5, rather than the range of x≦0.856.

Note that the arrow of FIG. 3 is shown for describing a difference between this embodiment and patent document 4.

First, in an oxygen gas ratio, etc., described in patent document 4, it appears that the first embodiment of patent document 4 shows the resist composition shown by arrow I of FIG. 3, and it appears that the second embodiment of patent document 4 shows the resist composition shown by arrow II of FIG. 3.

Meanwhile, this embodiment shows the resist composition shown by arrow III of FIG. 3. Thus, a well-balanced gradient composition of the optical-absorption coefficient and the thermal conductivity can be obtained, and as a result, high resolution can be obtained.

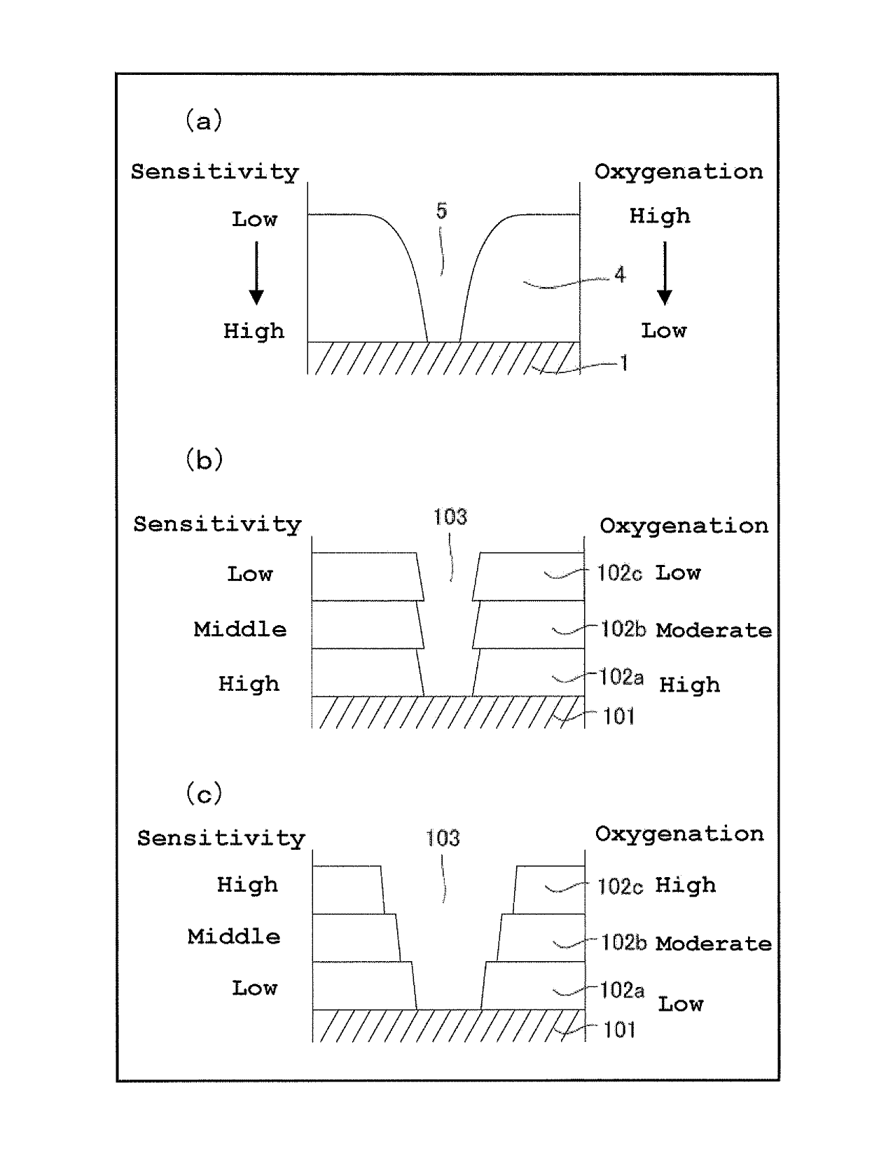

Further, as shown in FIG. 18(a) which is a schematic sectional view of the substrate 1 with inorganic resist 4 having a pattern formed thereon, according to this embodiment, the value of x in WOx is continuously decreased in the single layer resist 4, and the resist sensitivity is increased toward the depth direction of the resist. As a result, a temperature range showing a fixed temperature toward the depth direction of the resist has the anisotropy (FIG. 18(a), and a range shown by arrow III of FIG. 3). As a result, a smooth concave portion is formed by the inorganic resist.

Meanwhile, FIG. 18(b)(c), being schematic sectional views according to patent document 4, shows the resist sensitivity and the variation of the value of x different from those of this embodiment.

Namely, in the first embodiment (FIG. 18(b), shown by arrow I of FIG. 3), three layers of resist layers 104a to 104c are formed on the substrate 101, and the value of x in WOx is increased toward the depth direction of the resist between each resist layers, and the resist sensitivity is also increased. As a result, stepped concave portion 103 is formed as a resist pattern.

Further, according to the second embodiment of patent document 4 (FIG. 18(c), shown by arrow II of FIG. 3), three layers of resist layers are similarly formed, and the value of x in WOx is decreased toward the depth direction between each resist layers, and the resist sensitivity is also decreased. As a result, the stepped concave portion 103 is formed as a resist pattern.

At least in this embodiment, there is a large difference from the patent document 4, in the point of the resist sensitivity and the composition.

iii) Optical Characteristic (Optical-Absorption Coefficient)

Subsequently to the resist sensitivity, explanation will be given for the optical characteristic having an influence on the anisotropy of the area in which the temperature is fixed in the inorganic resist 4. As described above, the optical-absorption coefficient and the refractive index, etc., are included in the optical characteristics, and above all, it is the optical-absorption coefficient that gives an influence to the resolution of the resist, namely the anisotropy of the area in which the temperature is fixed.

When the optical-absorption coefficient is not excessively small, the aforementioned effect can be obtained, and when the optical-absorption coefficient is not excessively large, controllability of a formed pattern size can be maintained without causing an endothermic heat to be excessively large.

FIG. 1 shows a case that oxygen amount (x) may be continuously decreased within a range of x=2.7 (preferably x=2.5) on the main surface side of the resist, and x=0.485 on the rear surface side of the resist (interface side of the quartz substrate 1), when the material composition is defined as WOx.

Thus, the optical-absorption coefficient can be continuously increased in the depth direction of the resist.

iv) Thermal Characteristic (Thermal Conductivity)

Next, explanation will be given for the thermal characteristic having an influence on the anisotropy of the area in which the temperature is fixed. As described above, the thermal conductivity and the specific heat are included in the thermal characteristic, and above all, it is the thermal conductivity that gives an influence to the anisotropy of the area in which the temperature is fixed.

As shown in FIG. 2, the thermal conductivity is largely varied by the variation of the value of x in a range of 0<x≦5. Meanwhile, regarding the thermal conductivity of FIG. 2, there is an area in which the variation is extremely large (0<X<0.4), and there is an area in which the variation is moderately large (0.4≦x≦2.0), and also there is an area in which almost no variation occurs (x>2.0).

In the area in which almost no variation of the thermal conductivity occurs, best resolution can not be obtained even if the oxygen concentration (x) is set to be continuously small in the depth direction of the resist, so that the optical-absorption coefficient becomes continuously large in the depth direction of the resist (see FIG. 1, FIG. 2, and FIG. 3). This is because both influence of the optical-absorption coefficient and the thermal conductivity is excessively small.

Further, in the area in which the variation of the thermal conductivity is extremely large, even when the oxygen concentration (x) in the depth direction of the resist is set to be continuously small so that the optical-absorption coefficient in the depth direction of the resist is continuously large, this area is similar to the area in which almost no variation of the thermal conductivity occurs. It can be considered that this is because the resolution on the rear surface side of the resist is deteriorated because there is a great influence of an action of heat escape due to high thermal conductivity on the rear surface side of the resist (see FIG. 1, FIG. 2, and FIG. 3).

As a result, it is preferable to continuously vary the optical-absorption coefficient and the thermal conductivity, being characteristics of the resist having a function of improving the resolution of the resist from the main surface side to the rear surface side, so that one of them or both of them are not excessively high or excessively low.

Thus, both influences of the optical-absorption coefficient and the thermal conductivity are totaled, and as a result of synergistic action of both influences, the action/function of increasing the anisotropy of the temperature distribution and also the anisotropy of the change in its state (phase change) are improved, and the action/function of increasing the resolution of the resist is also improved.

Namely, the resist resolution characteristic value is preferably a value of one or more selected from the optical-absorption coefficient, the thermal conductivity, and the resist sensitivity.

Further, according to this embodiment, there is a correlation between a continuous variation of the composition and a continuous variation of the resist resolution characteristic value. Therefore, in order to increase the anisotropy of the temperature, the resist resolution characteristic value may be varied instead of varying the composition.

FIG. 2 shows a case that it is also acceptable that the oxygen amount (x) is selected within a range of x=2 on the main surface side of the resist, and x=0.485 on the rear surface side of the resist (interface side of the quartz substrate 1), when the material composition is defined as WOx.

Further, in the WOx-based inorganic resist 4, the optical-absorption coefficient and the thermal conductivity in the depth direction of the resist are preferably set to be continuously large, in consideration of the area in which the optical-absorption coefficient is varied, the area in which the thermal conductivity is varied, and the area in which the resist sensitivity is high, namely all three areas.

Specifically, when the inorganic resist 4 is expressed by WOx, preferably x is set to be in a range of 0.4≦x≦2.0 (preferably in a range of x including the maximum value of the resist sensitivity, namely, in a range of 0.856≦x≦2.0), and the value of x is continuously decreased from the main surface side of the resist irradiate with laser beams to the rear surface side of the resist.

Note that according to this embodiment, the aforementioned contents, namely,

(a) “The anisotropy is increased, in the area in which the temperature reaches to a fixed temperature when the resist is locally irradiated with the laser beams”

can be replaced with either one of the following contents:

(b) “Thermal anisotropy is increased in the area in which change in state (phase change) occurs when the resist is locally irradiated with the laser beams”, and
(c) “Degree of anisotropy is increased, being the anisotropy of heat transfer in a resist film when the heat is locally given to the resist or in the periphery thereof by the focused laser (difference in transfer of heat in a vertical direction and in a horizontal direction in the resist: called heat transfer anisotropy).

Note that in this specification, the prescribed anisotropy is simply abbreviated as “temperature distribution anisotropy”, “state change (phase change) anisotropy”, and “heat transfer anisotropy” in some cases.

Further, comprehensively and typically the prescribed anisotropy is simply called “anisotropy of the area in which the temperature is fixed”, or simply “anisotropy”.

3) Film Thickness

The functionally gradient inorganic resist 4 of this embodiment has excellent resolution. However, the resolution of a heat sensitive material (resist) depends on the film thickness, and therefore there is an appropriate range thereof. Specifically, the thickness of the single layer resist is preferably in a range of 5 nm or more and less than 40 nm.

Excellent resolution of the resist of this embodiment allows the resolution of 50 nm level to be achieved in the thermal lithography by the focused laser, provided that the thickness of the resist is less than 40 nm.

Further, a process for forming a pattern can be carried out, by having a film thickness of 5 nm or more of the resist, in consideration of preventing the resist film from thinning by several nm thickness due to slight melting of the resist during developing.

4) Structure of the Resist

Preferably, the single layer resist has preferably an amorphous structure in which the optical characteristic and the thermal characteristic are varied in a gradient manner in the depth direction of the resist

With this structure, formation of a fine pattern of 50 nm is achieved when the inorganic resist 4 is formed on the planar substrate 1, and also even when the inorganic resist 4 is formed on a cylindrical base material (as will be described later in another embodiment).

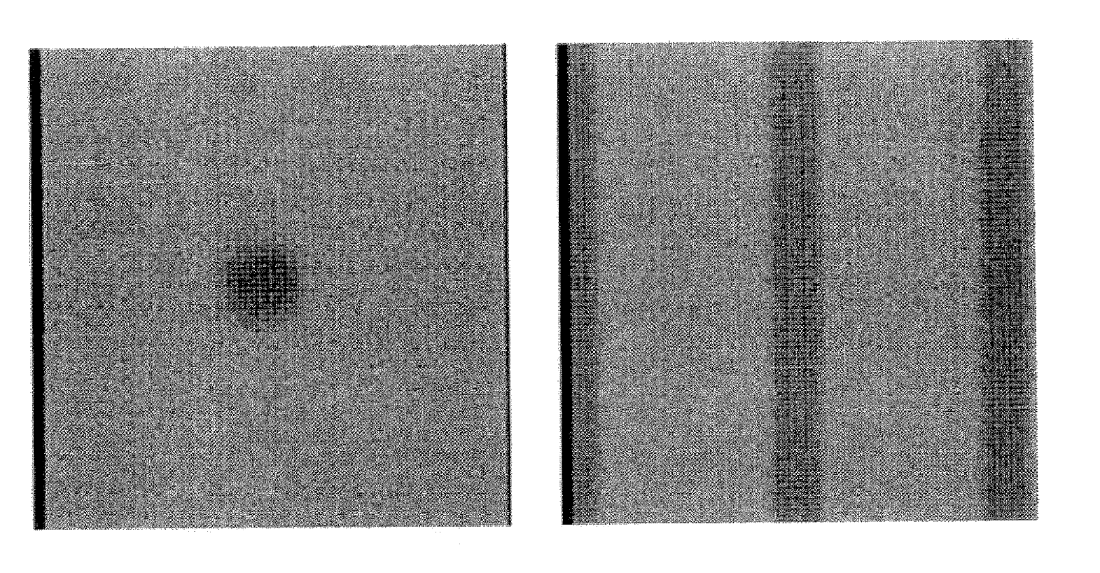

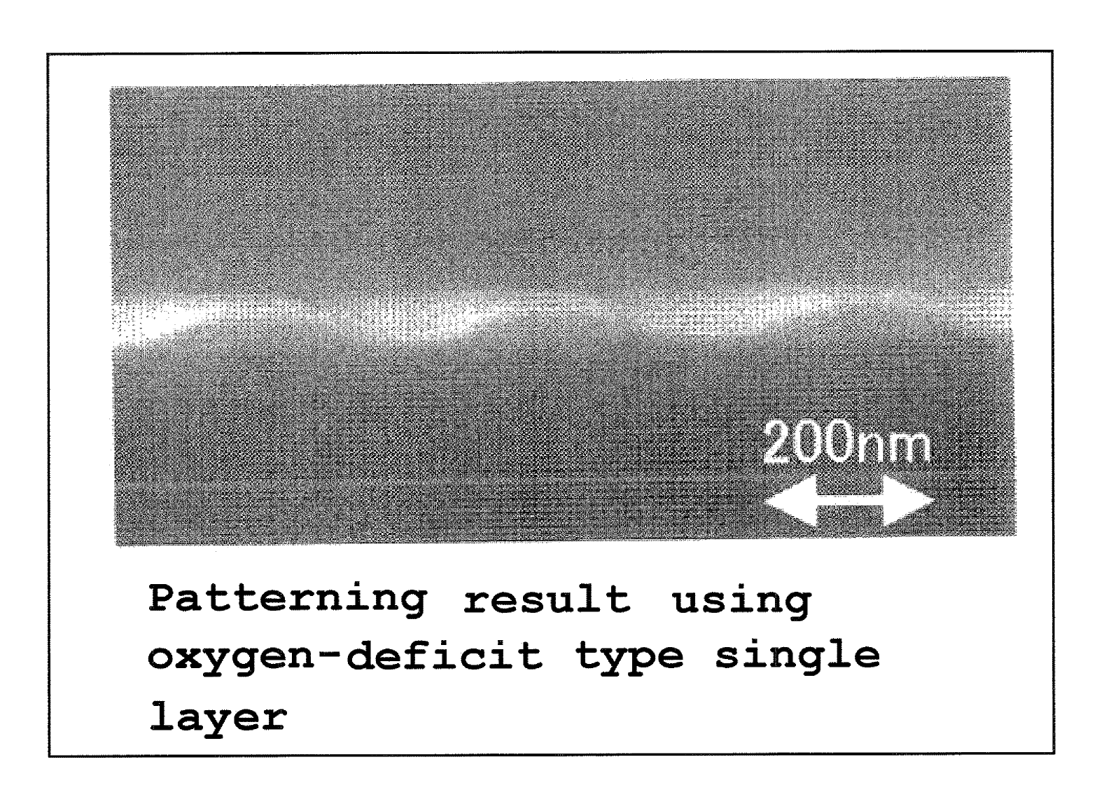

Namely, as shown in FIG. 10 and FIG. 11 in which after drawing a pattern using the focused laser beams, a sectional face of a resist pattern 5 after being developed using a general developing liquid, is evaluated using a scanning electron microscope (called SEM hereafter), and it is found that a sectional profile of the pattern size of the functionally gradient inorganic resist 4 of this embodiment is excellent (example 1), compared with the resolution of about 90 nm of the resist pattern (conventional example) obtained by a method described in patent document 1 (comparative example).

<3. Outline of a Substrate with Functionally Gradient Inorganic Resist>

Explanation will be given hereafter for an example of forming the inorganic resist 4 on the planar substrate 1, as one of the embodiments of using the aforementioned inorganic resist 4.

In this embodiment, a ground layer 2 is formed on the substrate 1, and an etching mask layer 3 is formed on the ground layer 2, and the inorganic resist 4 is formed on the etching mask layer 3.

Note that only one of the ground layer 2 and the etching mask layer 3 of this embodiment may be provided, or both layers may not be provided.

<4. Details of the Substrate with Functionally Gradient Inorganic Resist>

1) Substrate (Base Material)

This embodiment describes a case that the planar substrate 1 is used. A substance of a layer on which the inorganic resist 4 or the ground layer 2 can be provided, is not particularly limited, and it is also acceptable if the substance is included in the base material for forming the inorganic resist 4.

The substrate 1 is practically preferably made of a material mainly composed of any one of metal, alloy, quartz glass, multicomponent glass, crystalline silicon, amorphous silicon, amorphous carbon, glasslike carbon, glassy carbon, and ceramics.

2) Ground Layer

Further, preferably the ground layer 2 is made of a material of at least one or more of

(1) oxide, nitride, carbide of Al, Si, Ti, Cr, Zr, Nb, Ni, Hf, Ta, W, and a composite compound of them, or
(2) (i) amorphous carbon, diamond-like carbon, graphite comprising carbon, or carbide nitride comprising carbon and nitrogen (CxNy), or

(ii) at least one or more of the materials obtained by doping the material containing carbon with fluorine. This is because the material doped with fluorine has excellent mold releasing property.

The thickness of the ground layer 2 is preferably in a range of 10 nm or more and less than 500 nm. The characteristic of the ground layer 2 is satisfied by the thickness of 10 nm or more. Film formation with good quality is achieved by the thickness of less than 500 nm, and an adequate film stress can be obtained, thus not generating a separation of the film due to excessively high stress.

Note that the expression of “the substrate 1 with functionally gradient inorganic resist 4” in this embodiment, means the substrate 1 having the ground layer under the functionally gradient inorganic resist layer.

3) Etching Mask Layer

Further, according to this embodiment, the etching mask layer 3 is formed on the ground layer 2.

The etching mask layer 3 is obtained by applying etching to the ground layer 2 or the substrate 1 which are under the etching mask layer 3. Therefore, the etching mask layer 3 is required to have a high etching durability against halide etching main gas such as fluorine and chlorine, and an already used etching mask 3 is required to be selectively removed.

In order to obtain such a characteristic, the material of an etching mask is selected as follows. Namely

(1) a material of at least one or more of Al, Si, Ti, Cr, Nb, Ni, Hf, Ta, or a compound of them, unlike the ground layer 2 having W,
(2) (i) a material of at least one or more of amorphous carbon, diamond-like carbon, graphite comprising carbon, or a nitride carbide (CxNy) comprising carbon and nitrogen, or

(ii) a material of at least one or more of fluorine-doped carbon-containing materials,

is preferable.

Further, by selecting the material as described above, the pattern formation by etching applied to the ground layer 2 or the substrate 1 is facilitated, and also the thickness of the resist (namely heat-sensitive material) can be made further thinner.

Note that the separation of the film is easily generated because the performance of the etching mask is not satisfied by the thickness of 5 nm or less, when the thickness of the etching mask 3 is preferably in a range of 5 nm or more and less than 500 nm, thus making it difficult to form the film with good quality and increasing the stress of the film.

Materials of the ground layer 2 and the etching mask layer 3 are selected from a viewpoint of adhesiveness and low dispersability of the functionally gradient inorganic resist 4, the substrate 1, and the ground layer 2 of this embodiment, in addition to the aforementioned required characteristics, and with such a proper structure, the formation of a fine pattern having an excellent pattern depth is achieved.

Further, the aforementioned ground layer 2 and etching mask layer 3 made of the aforementioned materials, function as pattern formation layers by applying etching thereto, owing to the materials. Therefore materials of the ground layer 2 and the etching mask layer 3 require physical and chemical stabilities. There is no restriction in applying pattern formation to the ground layer 2, and therefore the pattern may be formed to pass through the ground layer 2 or may be formed up to a middle of the ground layer 2.

Further, only one of the ground layer 2 and the etching mask layer 3 may be provided.

4) Inorganic Resist

The inorganic resist 4 of this embodiment is formed on the aforementioned etching mask layer 3. Details of the inorganic resist 4 are described above.

<5. A Method for Manufacturing the Substrate with Functionally Gradient Inorganic Resist 4>

A method for manufacturing the substrate 1 with functionally gradient inorganic resist 4 will be described hereafter. In this embodiment, the method will be described based on a case that the inorganic resist 4 is formed on the substrate 1. Then, the method will be described in a case that the aforementioned ground layer 2 and etching mask layer 3 are formed, as a preferable example of this embodiment.

1) Formation of the Functionally Gradient Inorganic Resist

First, a quartz substrate 1 is used as a base material, and a tungsten oxide film is formed on the quartz substrate 1 by reactive sputtering using a general tungsten target, sputtering gas, and oxygen gas.

At this time, the composition of the single layer resist is continuously varied from the main surface side to the rear surface side by continuously varying at least one of a gas partial pressure, a film forming rate, and a film forming output, upon forming the single layer resist.

Here, for example the oxygen concentration, namely the composition ratio of tungsten (W) and oxygen (O) in the resist film is continuously varied, by continuously varying an oxygen partial pressure in the sputtering gas during film formation. The oxygen ratio in the film is increased and the tungsten ratio in the film is decreased, as the oxygen partial pressure during film formation is increased.

At this time, the sputtering gas used for a sputtering target is selected from any one of oxygen, nitrogen, oxygen and nitrogen, oxygen and inert gas, oxygen and nitrogen and inert gas, and nitrogen and inert gas. Then, the inorganic resist 4 may be formed by reactive sputtering under this atmosphere.

Each kind of fundamental properties is examined based on the aforementioned basic characteristics, and the composition varied in a gradient manner in the depth direction of the resist is properly adjusted by computer simulation, for example in such a way that the composition ratio of the W/O-based inorganic resist 4 is set in a range of 4:1≦[inorganic resist composition ratio (W:O)]≦1:2.5, namely, the value of x in WOx is set to 0.25 or more and 2.5 or less. Then, the functionally gradient inorganic resist 4 is formed on the quartz substrate 1 while adjusting the film forming condition to obtain a proper composition.

The functionally gradient inorganic resist 4 of this embodiment is composed of suboxide (or defective oxide) or suboxide and subnitride (or defective oxynitride), or subnitride (or defective nitride), which is lack in oxygen, oxygen and nitrogen, or nitrogen composition from a theoretical composition of the aforementioned material (for example, WO₃ in a case of tungsten, CrO₂ in a case of chromium), and based on this fact, preferably the composition is continuously varied in the depth direction of the resist.

Even in a case of the suboxide (or defective oxide) or suboxide and subnitride (or defective oxynitride), or subnitride (or defective nitride) wherein the composition is set in a prescribed range, they are not included in this embodiment when the composition in the resist film is not continuously varied.

Here, means for continuously varying the optical-absorption coefficient and/or the thermal conductivity in the depth direction of the resist includes for example,

(1) continuously varying oxidizing degree, nitriding degree, and oxynitriding degree in the depth direction of the resist,
(2) continuously varying density of the film in the depth direction of the resist, and
(3) continuously varying the ratio of A and B in the depth direction of the resist, when the material composition of the inorganic resist 4 is defined as ABOx (A and B are different metals).

Thus, the characteristic of the resist having the function of improving the resolution of the resist, for example, functions such as the thermal conductivity, the refractive index, and the optical-absorption coefficient, can be continuously varied, namely, varied in a gradient manner in the depth direction of the resist.

Note that as described above, in order to have the anisotropy of the inorganic resist 4 in the depth direction of the resist in the area in which the temperature is fixed, the degree of oxidation may be continuously decreased in the depth direction of the resist in the aforementioned means (1). In addition, or instead, the density of the film may be set to be continuously larger in the depth direction of the resist in the aforementioned means (2).

Note that as described above, the ground layer 2 may be previously formed under the resist, other than the substrate 1 with functionally gradient inorganic resist 4 formed thereon for forming patterns (called a high resolution resist substrate 1 or substrate 1 with resist hereafter) and inorganic resist 4. Thus, a high aspect pattern can be formed.

Further, the etching mask layer 3 may be formed under the ground layer 2. Thus, further high aspect pattern can be formed.

Note that a similar method as the method for forming the inorganic resist 4 may be used as a specific method for forming the ground layer 2 and the etching mask layer 3.

Note that the reactive sputtering by ion beam is used in this embodiment. However, a method is not particularly limited provided that it is capable of forming the resist on the base material, and instead of the reactive sputtering method, a method for continuously varying the oxygen concentration in a gradient manner, being a vacuum film forming method, can also be used.

2) Formation of a Fine Pattern on the Resist

In this embodiment, drawing or exposure is carried out by the focused laser beams, to the substrate 1 on which the functionally gradient inorganic resist 4, the etching mask layer 3, and the ground layer 2 are formed sequentially from the main surface side of the resist to the substrate 1, to thereby locally form a part that is changed in its state on the inorganic resist 4, and form a fine pattern by a dissolution reaction by development.

Specifically, the high resolution resist substrate is set on a stage of a commercially available laser drawing device, to thereby carry out drawing.

A laser structure of the drawing device is mainly formed of a laser head for reading/writing an optical disc such as CD and DVD, at an extremely low cost as a drawing device. See U.S. Pat. No. 3,879,726 and non-patent document 2 for example, for the specification of the drawing device.

Note that a laser oscillation method here generally includes a pulse oscillation method and a continuous oscillation method. However, there is no restriction in drawing, and the laser oscillation method can be selected so as to suit to the purpose of use. Further, a desired pattern can be formed on the planar substrate 1 by using an X-Y stage in addition to a rotary stage as a drawing stage.

The pattern is drawn on the resist by constantly adjusting and focusing the laser irradiation to the resist, as a characteristic function. Then, owing to this function, by constantly controlling the height of an objective lens, excellent stability in a dimension of a drawing pattern can be obtained.

Here, a drawing system can be selected inconformity with the purpose of use. For example, a drawing device composed of X-Y stage is used for drawing a straight line or a dot pattern on the planar substrate 1.

Further, a high resolution resist substrate is set on the rotary stage precisely for the purpose of drawing a concentric circle patterns for discrete track media for example, and a drawing point is precisely stepwise-moved with respect to a head portion set on one-axial stage with laser mounted thereon while rotating the rotary stage when not drawing the pattern, thus carrying out drawing in a halt state, to thereby carry out resist drawing for forming the concentric pattern.

3) Formation of a Fine Pattern on the Substrate

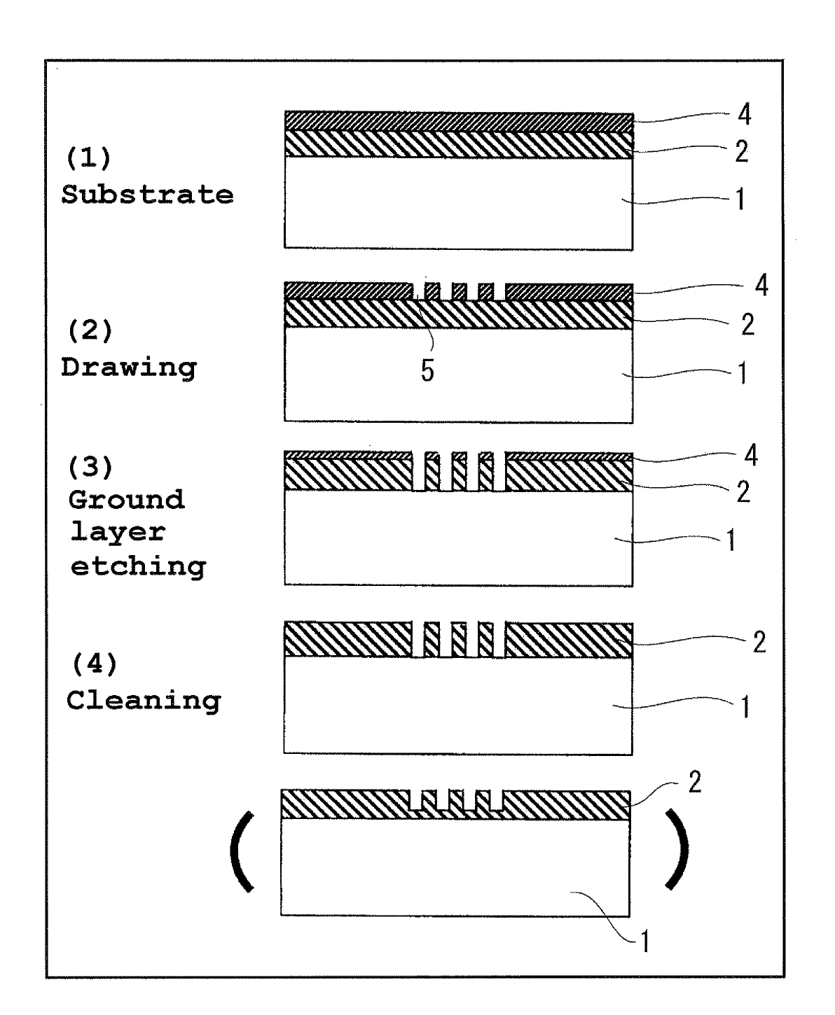

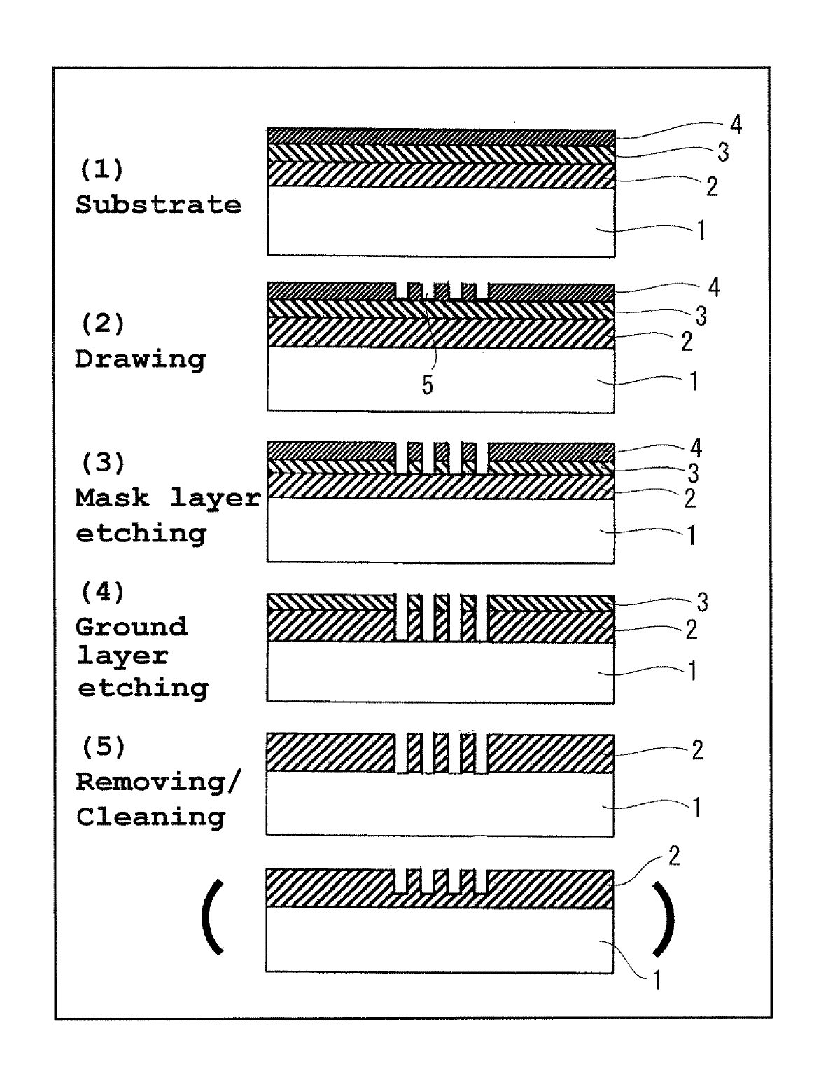

Pattern formation is applied to the high resolution resist, and etching process is applied to the substrate 1, using the inorganic resist having this pattern as an etching mask, to thereby form the pattern on the substrate 1. FIG. 5 shows this process. Further, FIG. 6 shows a process when providing the aforementioned ground layer 2, and FIG. 7 shows a process when further providing the etching mask layer 3.

Usually, extremely thin inorganic resist 4 with a film thickness of less than 40 nm makes it difficult to form patterns thereon having a depth of multiples of the thickness of the resist, because the film thickness is thin for the etching process applied to the base material, and etching selectivity between the base material and the inorganic resist 4 is not high so much.

However, a high aspect pattern can be formed by previously forming the material of the ground layer 2 on the high resolution resist substrate.

A fine pattern forming method using the ground layer 2 will be described using FIG. 6. The pattern is drawn on the high resolution resist accompanying the ground layer 2, by thermal lithography using the focused laser beams.

At this time, the ground layer 2 is suitable for forming a further fine resist pattern, provided that the thermal conductivity is lower than 3 W/m·K, and the optical-absorption coefficient is in a range of 1 to 3.

Subsequently, the pattern is formed on the high resolution resist on the ground layer 2 by development, and thereafter the resist pattern 5 is transferred to the ground layer 2, to thereby obtain the pattern of the ground layer 2.

At this time, high etching selectivity (etching rate) can be obtained for the inorganic resist 4, by optimizing the condition such as etching gas, under the aforementioned condition regarding the material of the ground layer 2.

Thus, the ground layer 2 has the material to function as a pattern formation layer, and there is basically no restriction in forming the pattern on the ground layer 2, thus allowing the pattern to pass through the ground layer 2 (see FIG. 6(4)), or stop in the middle of the ground layer 2 (see an embodiment shown by parenthesis in FIG. 6).

Next, a method for forming a fine pattern using the etching mask layer 3, will be described using FIG. 7. The pattern is drawn on the high resolution resist accompanying the etching mask layer 3 and the ground layer 2, by thermal lithography using the focused laser.

At this time, similarly to the ground layer 2, the etching mask layer 3 is also suitable for forming a further fine resist pattern, provided that the thermal conductivity is lower than 3 W/m·K, and the optical-absorption coefficient is in a range of 1 to 3.

Subsequently, the pattern is formed on the high resolution resist on the etching mask layer 2 by development, and thereafter the resist pattern 5 is transferred to the etching mask layer 3, to thereby form the pattern on the etching mask layer 3.

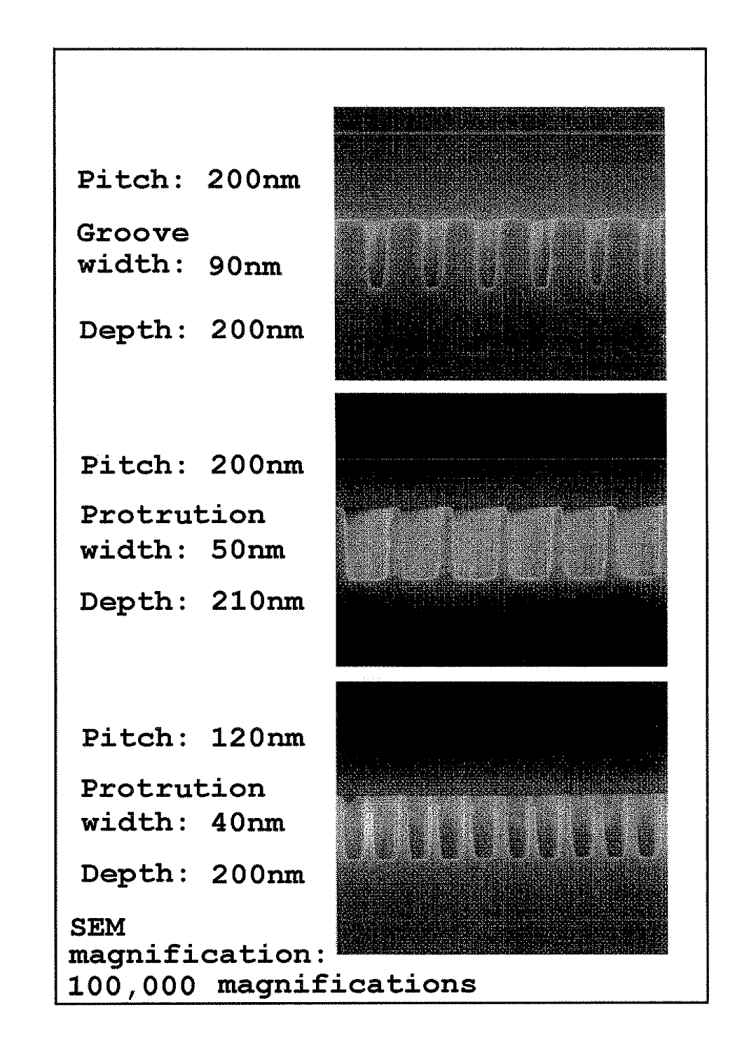

FIG. 16 shows an evaluation of a sectional face of a sample in which etching is applied to the substrate 1 by a fine pattern formation process shown in FIG. 7 (wherein the ground layer 2 is not formed) after the functionally gradient inorganic resist 4 and the etching mask of this embodiment are formed on the quartz wafer.

From this evaluation result, it is confirmed that a fine pattern having a depth of 200 nm or more can be formed on the quartz substrate 1 even in a case of an extremely thin inorganic resist 4, by an effect of the etching mask layer 3 whose material is selected in consideration of required characteristics.

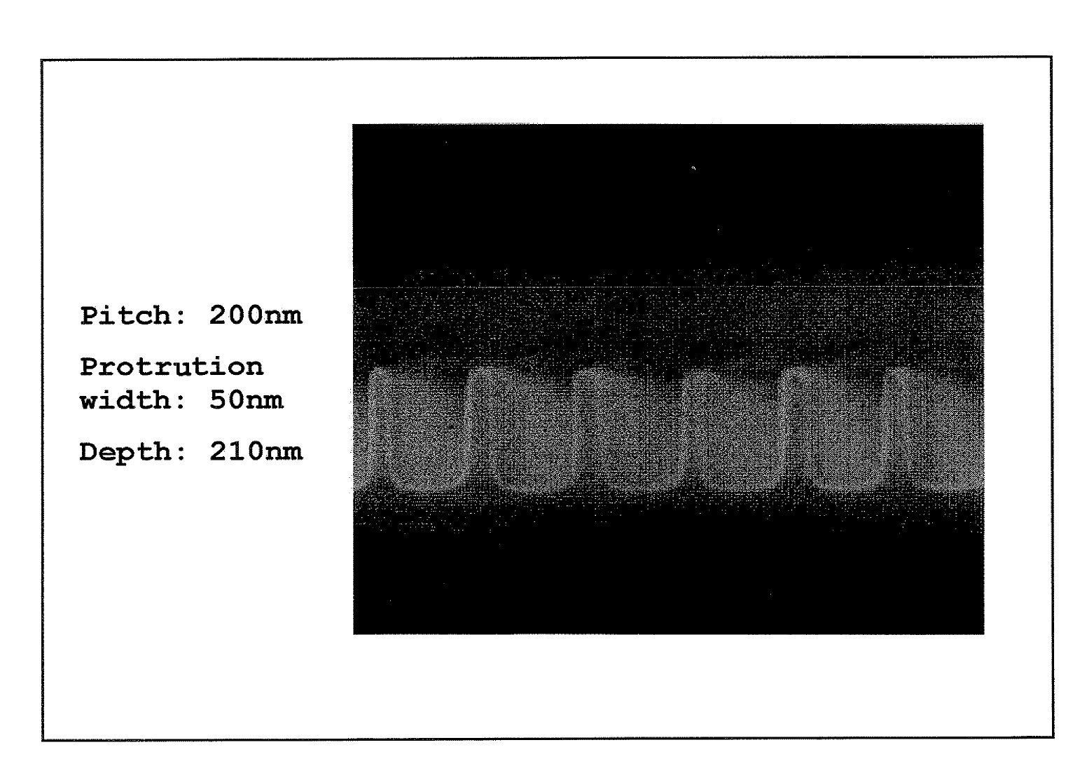

Further, FIG. 17 shows a result of SEM evaluation after selectively removing the already used etching mask. The result reveals formation of an excellent fine pattern, high resolution of the functionally gradient inorganic resist 4 of this embodiment, and effectiveness of the etching mask layer 3.

Note that the ground layer 2 functions as the pattern formation layer by applying etching process thereto, and the material of which requires physical and chemical stability.

Meanwhile, the etching mask layer 3 has lower layers of the ground layer 2 and the substrate 1, and the etching process is applied to the ground layer 2 or the substrate 1, thus requiring characteristics of high etching durability against halide etching main gas such as fluorine and chlorine, and selectively removing an already used etching mask 3.

According to the aforementioned method, resist resolution of 50 nm level is achieved by a phase change lithography (or thermal lithography) method using the focused laser as a light source, which can't be realized heretofore, and which is expected to be developed for the purpose of use requiring a fine pattern formation of 100 nm or less such as a magnetic recording device like discrete track media, and a display device such as LCD (Liquid Crystal Display) and EL (Electra Luminescence), and an optical element.

Further, the resist resolution of 50 nm level which is not achieved heretofore, can be achieved by optimizing the structure of a material and a film thickness of the base material, functionally gradient inorganic resist 4, ground layer 2, and etching mask layer 3, and by combining the substrate 1 with functionally gradient inorganic resist 4, the drawing process applied to the substrate 1 accompanying functionally gradient inorganic resist 4 by the focused laser beams with a wavelength in a range of 190 nm to 440 nm, and development using organic or inorganic alkali-based developing solution.

<6. Explanation for the Effect of the Embodiment>

This embodiment has an effect described as follows.

Namely, in the high resolution inorganic resist 4 of this embodiment, resist formation of 50 nm level is achieved for the first time, by the phase change lithography (or thermal lithography) method using the focused laser beams as the light source, which is not realized heretofore.

Further, in the high resolution inorganic resist 4 of this embodiment, a fine pattern of 50 nm level can be formed on the surface of the planar substrate 1 and the pattern formation layer, being a surface layer of the planar substrate 1 (called the ground layer 2 in this specification), by applying etching process to the resist pattern 5 on the planar substrate 1.

As a result, a mask or a mold with fine patterns formed thereon can be fabricated at a further lower cost than the cost of a conventional method.

Accordingly, such a mask or a mold can be developed for the purpose of use requiring the fine pattern formation of 50 nm level such as a magnetic recording device, a display device such as LCD, and an optical element.

As described above, the resist resolution in a case of the thermal lithography using the focused laser beams can be improved to 50 nm level or more when the planar substrate 1 is used, and since this technique can be applied to a roller mold as will be described later, the fine pattern in a large area can be formed at a low cast.

### Second Embodiment

A technical range of the present invention is not limited to the aforementioned embodiment, and includes various modifications and improvements within a range capable of deriving a specific effect obtained by constituting features of the present invention and a combination thereof.

Modified examples of the embodiment 1 will be described hereafter in detail. Note that in the embodiments described hereafter, a portion not particularly specified is the same as that of the embodiment 1.

In this embodiment, the functionally gradient resist material comprises a first material composed of at least one of suboxide, nitride, or suboxinitride of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and a second material composed of at least one of the above elements excluding the first material.

Then, compositions of the first material and the second material are relatively and continuously varied from the main surface side to the rear surface side.

In this case, the relative composition (ratio) of the first material and the second material is preferably varied in a range in which the anisotropy is continuously and relatively increased toward the depth direction of the resist, which is the anisotropy of the area where the temperature reaches a fixed temperature when the material is locally irradiated with the laser beams.

Further, the relative composition (ratio) of the first material and the second material is preferably varied in a range of relatively increasing the resolution, namely a degree of the resolution limit, preferably in a range of allowing the resolution limit to be highest.

In addition, further another resist may be provided on the main surface side and/or the rear surface side of the single layer resist. At this time, it is further preferable that another resist according to the embodiment 1 or this embodiment is used.

### Embodiment 3

Although the substrate 1 is used in the embodiment 1, in this embodiment, explanation will be given for a case that a cylinder-shaped base material (also called a cylindrical base material hereafter) is used instead of the substrate 1.

In this embodiment, the ground layer 2 is formed on the surface of the cylindrical base material, and the functionally gradient inorganic resist 4 is formed on the ground layer 2. Then, the cylindrical base material with resist is precisely set on the rotary stage of the laser drawing device. Subsequently, drawing or exposure and development are implemented on the inorganic resist 4 so as to be patterned into a desired shape, by the thermal lithography using the focused laser beams having an automatic focusing function, while rotating the cylindrical base material with resist. Then, the resist pattern 5 is transferred to the ground layer 2 by etching, and the pattern of the ground layer 2 is formed on the cylindrical base material.

Further, when a concentric pattern is drawn on the cylindrical base material, a laser head is approached to the cylindrical base material fixed to the rotary stage, and a drawing point is precisely stepwise-moved with respect to the head portion set on one-axial stage with laser mounted thereon, while rotating the cylindrical base material when not drawing the pattern, thus carrying out drawing in a halt state. Further, in a case of forming a spiral pattern, drawing is carried out while continuously and slightly moving the one-axial stage with laser head mounted thereon.

At this time, as described in the embodiment 1, the inorganic resist 4 may have an amorphous structure in which the thermal characteristic and the optical characteristic are varied in a gradient manner in the depth direction of the resist.

Based on the aforementioned method, as will be described later in examples, the pattern resolution of 100 nm level is successfully achieved in spite of the roller mold.

Therefore, a fine pattern and a field linking system, which are conventional problems involved in fabricating the roller mold can be solved. In order to fabricate the roller mold, a flexible thick nickel mold is fabricated by applying nickel (Ni) electroforming plating to a master plate (original plate) which is fabricated using a semiconductor lithography, and the thick nickel mold of a single body or a plurality of overlapped bodies is wound around the cylindrical base material.

As a result, resist pattern formation of 100 nm level, namely, fine pattern formation of 100 nm level, is achieved not only on the flat plate but also on the cylindrical base material, by the thermal lithography using a general focused laser beams as the light source, which is not achieved heretofore.

As a result, such a fine pattern forming method can be applied to a large display device component and a large illumination component like LCD and EL, in combination with a roll nano-imprint method using a cylindrical mold having a fine line pattern or a rectangular (hole or dot) pattern of 100 nm level.

Note that although this embodiment describes the cylindrical base material, it is a matter of course that a technical concept of the present invention can be applied to a three-dimensional structure in addition to the substrate 1 and the cylindrical base material.

### Embodiment 4

In this embodiment, an optimal gradient range of the “composition” is selected, and further a gradient direction and a gradient amount (difference between a maximum value and a minimum value) are selected, so that the resolution limit is optimized (preferably increased).

As a means for optimizing the resolution limit, preferably an optimal gradient range of the “composition” is selected by obtaining a relation between the “composition” of the single layer inorganic resist 4 without gradient composition in the depth direction of the resist, and the “optical-absorption coefficient, thermal conductivity, and resolution pattern dimension” (for example, by obtaining the relation shown in a graph similar to the graphs of FIG. 1, FIG. 2, and FIG. 3), so that the resolution limit is optimized (preferably the resolution limit is increased), in consideration of a degree of influence on the resolution limit by the “optical-absorption coefficient, thermal conductivity, sensitivity defined by the resolution pattern dimension”.

For example, the relation between the “composition” of the single layer inorganic resist 4 and the “resolution pattern dimension” is obtained, and the gradient range can be obtained so that the “composition” at a point of the maximum value (highest value of the resolution pattern dimension) in the obtained graph is the composition on the rear surface side of the resist.

Note that tendencies shown in FIG. 1, FIG. 2, and FIG. 3 are different depending on the material and the composition of the inorganic resist 4, and therefore the optimal gradient range needs to be obtained in association with the material and the composition, etc., of the inorganic resist 4. Particularly, the maximum value shown in FIG. 3 is shifted to right and left depending on the material of the ground layer, and therefore the optimal range needs to be obtained in association with the material of the ground layer 2.

### Embodiment 5

In the aforementioned embodiment, explanation is given for the method for obtaining the high resolution by continuously increasing the anisotropy of the area in which the temperature is fixed, from the main surface to the rear surface of the resist.

Meanwhile, in this embodiment, as shown in FIG. 3, the resolution pattern dimension (sensitivity of the resist) has a maximum value where the resist sensitivity becomes high, with an increase of the oxygen concentration, and this point is focused.

Specifically, the composition on the rear surface side of the inorganic resist 4 allows the resist sensitivity to show maximum in the relation between the composition of the functionally gradient inorganic resist and the resist sensitivity.

Thus, the composition of an arbitrary element of the inorganic resist 4 is varied from the main surface side to the rear surface side, with the composition on the rear surface side of the inorganic resist fixed to the composition allowing the resist sensitivity to have the maximum value.

At this time, as described in the aforementioned embodiment, the density of the inorganic resist 4 may be varied instead of varying the composition of the arbitrary element. Further, the composition and the density may be varied simultaneously.

With this structure of the inorganic resist 4, the rear surface side of the inorganic resist 4 can be set in a state that the resist sensitivity is most excellent, depending on the kind of the resist. Thus, the pattern can be excellently transferred to immediately under the inorganic resist 4.

Further, when the inorganic resist 4 has the maximum resist sensitivity, there is also an advantage that excellent pattern transfer can be obtained, without being restricted by the kind of the inorganic resist 4.

Further, when the composition on the rear surface side of the inorganic resist 4 is fixed to the composition allowing the resist sensitivity to have the maximum value, the composition of the arbitrary element may be decreased or may be increased from the main surface side to the rear surface side of the inorganic resist 4. The density may also be decreased or may be increased.

Further, this embodiment is not limited to a case of varying the composition and the density in the single layer resist as described in the aforementioned embodiments.

Namely, it is also acceptable to use a resist not included in the “single layer resist” in the embodiment 1, namely a resist formed by starting the resist film formation under a certain film forming condition, and continuing the film formation while maintaining the condition, and thereafter non-continuously varying the condition to another film forming condition, and forming the film under another film forming condition.

Thus, the inorganic resist 4 with a multilayer structure may be used. This is because by fixing the composition on the rear surface side of the inorganic resist 4, to the composition allowing the resist sensitivity to have the maximum value, the most excellent state of the resist sensitivity can be obtained even when the resist is not the single layer resist.

To described in an extremely manner, the inorganic resist 4 may not be the functionally gradient inorganic resist, but may be the inorganic resist with fixed composition and/or density in the inorganic resist 4.

However, as described in the embodiment 1, the composition of the arbitrary element is preferably decreased from the main surface side to the rear surface side of the inorganic resist 4, in a point that the anisotropy is continuously increased in the area in which the temperature is fixed.

Particularly, in order to use WOx for the inorganic resist 4, the value of x is preferably decreased from the main surface side to the rear surface side.

Note that if the resist sensitivity is substantially extremely excellent, the resist composition (the value of x) on the rear surface side may be slightly deviated from the value of x, at a point where the resist sensitivity has the maximum value.

### EXAMPLES

Examples of the present invention will be specifically described next. Of course, the present invention is not limited to the examples given hereafter.

Note that the examples are described in the following order.

1. A case that the inorganic resist is provided on the substrate.

1) Example 1

2) Comparative example 1

3) Comparative example 2

2. A case that the ground layer and the inorganic resist are provided on the substrate (example 2)

3. A case that the ground layer, the etching mask, and the inorganic resist are provided on the cylindrical base material (example 3)

### 1. A Case that the Inorganic Resist is Provided on the Substrate

### Example 1

In example 1, tungsten oxide (WOx) was used as a heat-sensitive material, and effectiveness was examined using a high resolution resist with oxygen concentration continuously varied in a gradient manner, wherein the oxygen concentration range was selected based on a relation between characteristic (functions) of the sensitivity defined by the optical-absorption coefficient, thermal conductivity, and resolution pattern dimension shown in FIG. 1, FIG. 2, FIG. 3, and oxygen amount (x) when the material composition is defined as WOx.

First, the inorganic resist 4 composed of tungsten oxide with a composition gradient structure, was formed on a precisely polished quartz substrate 1, in a film thickness of 20 nm. The thermal conductivity of the quartz substrate 1 was evaluated by a laser heat reflection method and the thermal conductivity of 1.43 W/m·k was shown.

A proper gradient composition of the inorganic resist 4 was examined using the quartz substrate 1 having the aforementioned characteristics, and excellent gradient composition was found when the value of x is continuously varied so that the oxygen amount (x) is expressed as x=1.60 on the main surface side of the resist, and x=0.85 on the rear surface side of the resist (interface side of the quartz substrate 1) when the material composition was defined as WOx. Specifically, an oxygen gas ratio was continuously varied from about 15% to about 25%, and sputtering was carried out from the rear surface side to the front surface side.

Note that Rutherford Back Scattering Spectroscopy (RES) was used for analyzing the composition of the inorganic resist 4.

Subsequently, the quartz substrate 1 with high resolution resist, being the quartz substrate on which the inorganic resist 4 was formed, was set on a stage of commercially available laser drawing equipment, and the focused laser beams was used to focus and irradiate the main surface of the resist while moving (or rotating) the substrate 1 at a prescribed speed, under a condition allowing the phase change of the inorganic resist 4 to occur by the laser beams having an automatic focusing function, to thereby carry out drawing on the inorganic resist 4.

Note that the laser beams used at this time were blue semiconductor laser beams with a wavelength of 405 nm, and the numerical aperture (NA) of a laser optical system was set to 0.85. Laser irradiation power under this condition was set in a proper range of 6 to 12 mW.

Next, the substrate 1 with high resolution resist already used for drawing thereon, was developed by a commercially available developing solution, to thereby obtain the resist pattern 5. After finishing the development, the substrate 1 was washed by pure water and dried by IPA vapor, to thereby end the pattern forming process.

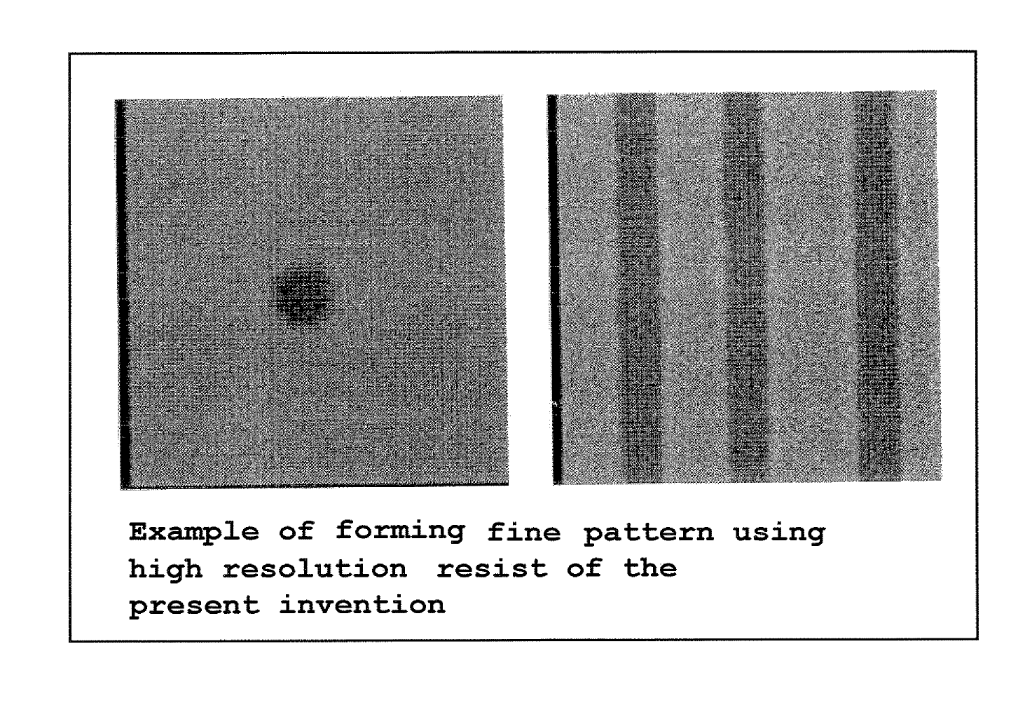

FIG. 8 shows an observation example of the resist pattern 5 using SEM. In this figure, a portion irradiated with laser beams was dissolved by the developing solution, and a so-called positive pattern in the lithography was formed, wherein a pattern edge was sharpened, thus providing an excellent contrast.

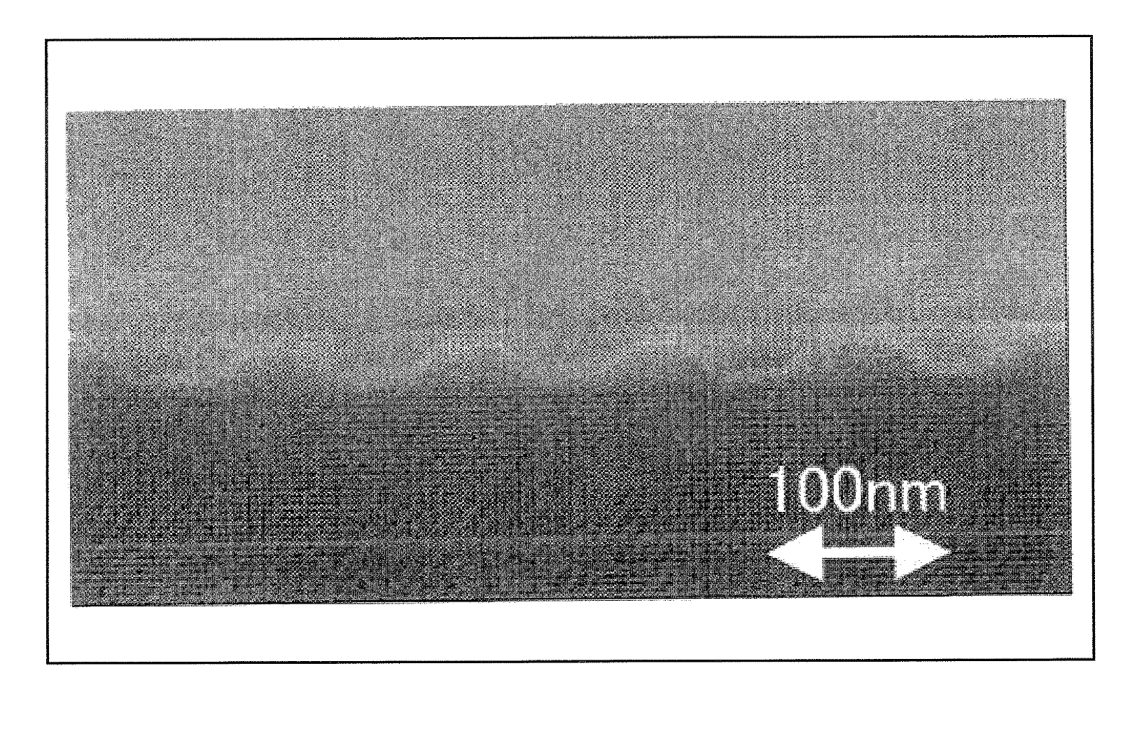

Then, the resolution was examined using the high resolution resist of this example, and it was confirmed that a fine pattern of 51 nm to 53 nm could be formed as shown in FIG. 9. Namely, the resolution of 50 nm level was achieved by using the high resolution resist of the present invention, which was conventionally not achieved by the drawing using the blue semiconductor laser.

### Comparative Example 1

As a typical example of the inorganic resist composition described in patent document 1 (Japanese patent Laid Open Publication No. 2003-315988), the inorganic resist 4 was formed on the quartz substrate 1 in a thickness of 20 nm, with oxygen amount fixed to x=1.5 in a case of WOx. Here, the resist film thickness was fixed, so that film thickness dependency was taken into consideration. The resolution characteristic was evaluated hereafter in a process similar to the process of example 1, using the same apparatus as the apparatus of example 1.

FIG. 10 shows an evaluation result obtained by SEM. In this case, a sufficient SEM contrast could not be obtained, due to poor profile of a pattern side wall and tapered shape of the pattern side wall.

This was confirmed by cross-sectional evaluation, and it was found that there was already a resolution limit at a pattern pitch of 200 nm as shown in FIG. 11.

At this time, a line pattern width of a laser irradiation part was 90 nm, thus not achieving a line pattern resolution of 50 nm level which was achieved by the high resolution resist of the present invention.

### Comparative Example 2

The inorganic resist 4 was prepared, which was modulated while the oxygen concentration was non-continuous as described in patent document 4 (WO2005/055224), and the resolution was evaluated.

According to Patent document 4, the resist sensitivity is increased as the oxygen concentration in the inorganic resist 4 is increased from the main surface side to the rear surface side of the resist (interface side of the substrate 1).

Namely, according to patent document 4, an angle of the side wall of the resist approaches to be vertical by increasing the oxygen concentration, with an increase of the depth of the resist (FIG. 2 of patent document 4).

Therefore, two kinds of samples (A and B) were prepared, in which the oxygen concentration in the inorganic resist 4 was increased from the main surface side to the rear surface side of the resist (interface side of the substrate 1), to thereby evaluate the resolution.

As the composition of the sample A, the oxygen amount x on an uppermost surface of the resist was set to 0.45, and the oxygen amount x on the rear surface side of the resist (interface side of the substrate 1) was set to 0.85, in a case of WOx.

Further, as the composition of the sample B, the oxygen amount x on the uppermost surface of the resist was set to 0.85 and the rear surface side of the resist (interface side of the substrate 1) was set to 1.60, in a case of WOx.

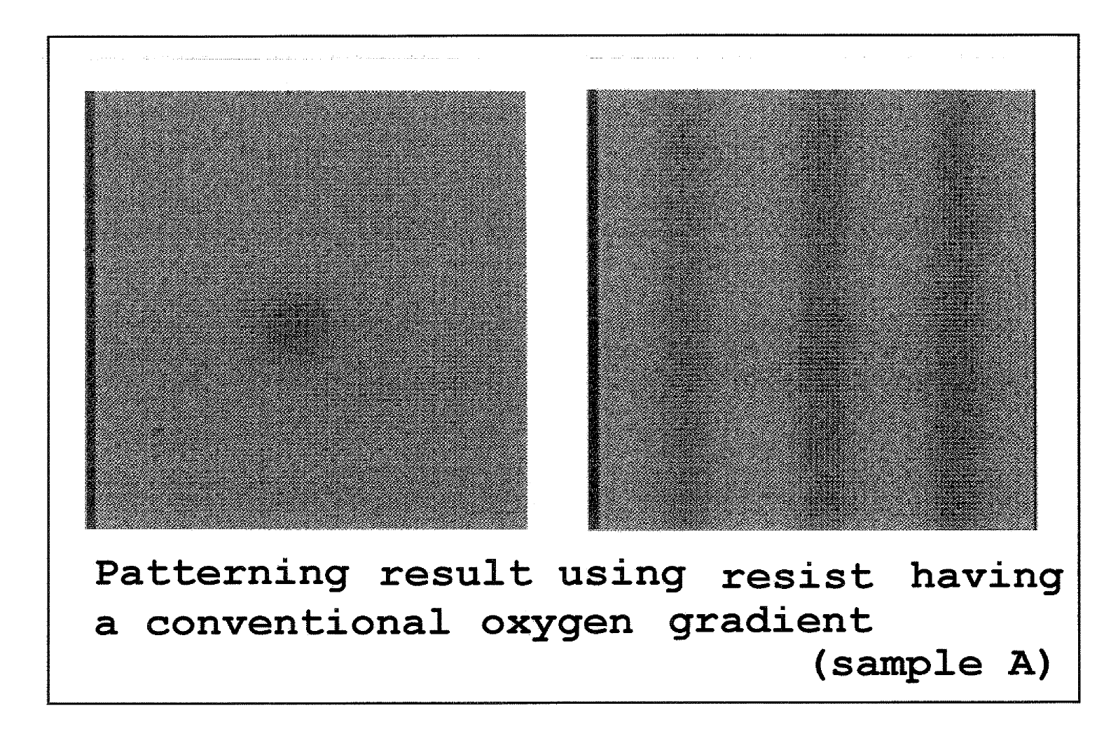

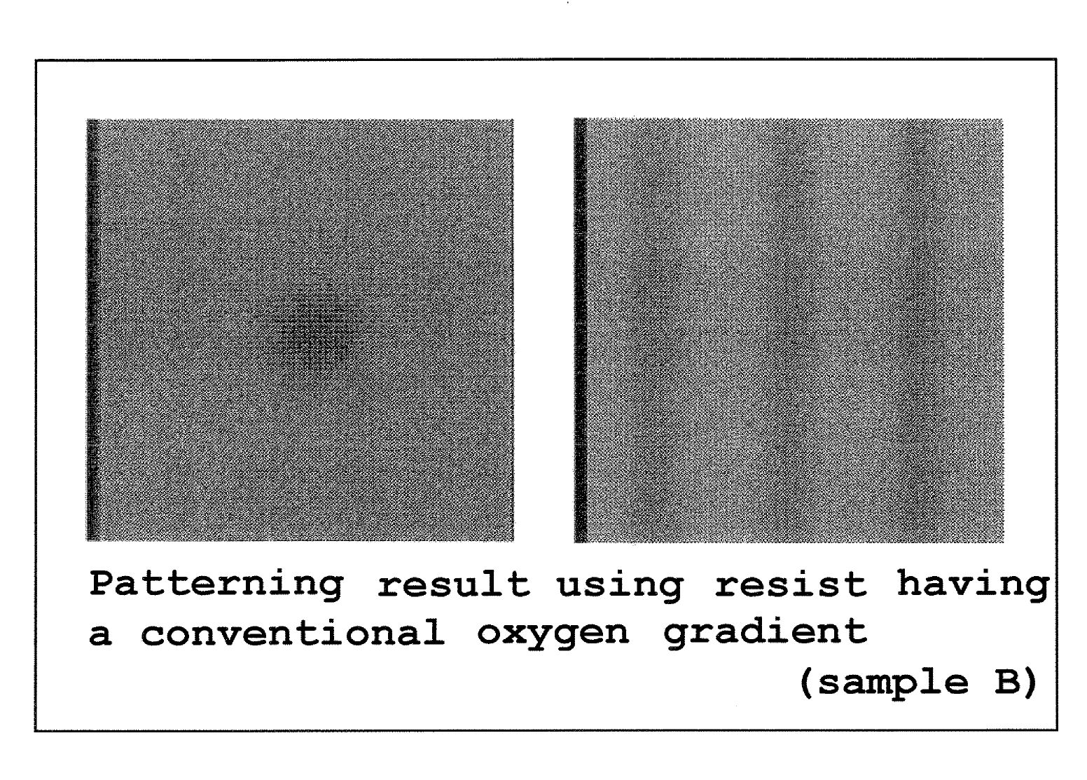

FIG. 12 and FIG. 13 show patterning evaluation results of samples A and B. As shown in FIG. 12 and FIG. 13, the sample A and the sample B couldn't be properly focused by SEM observation.

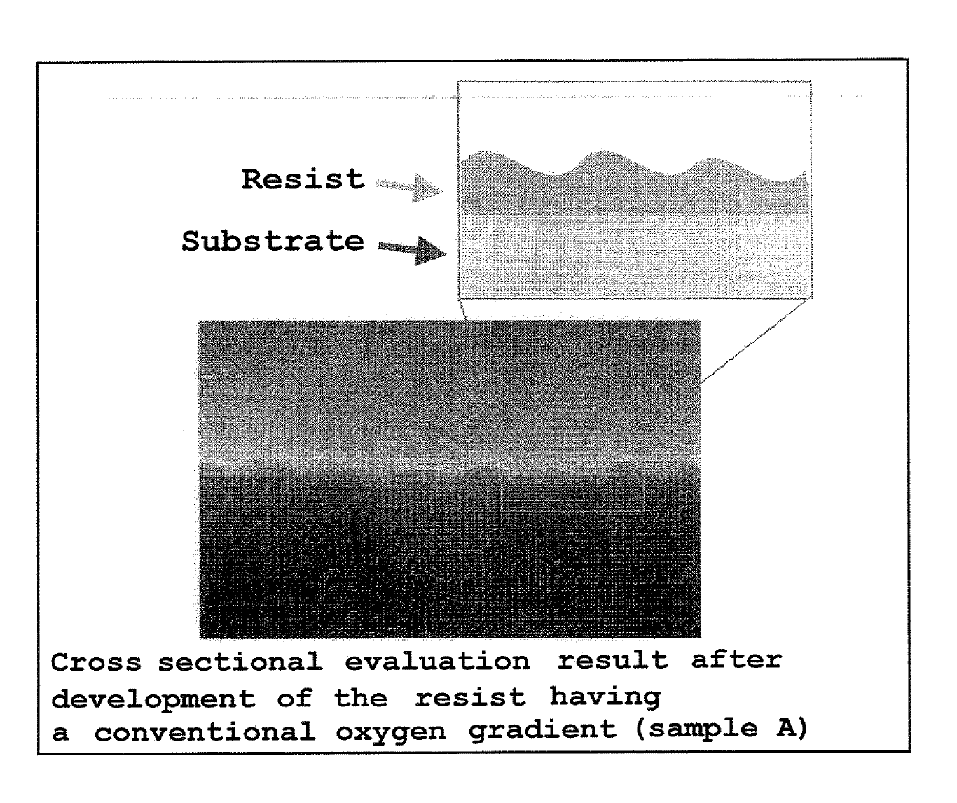

Therefore, cross-sectional evaluation was carried out by SEM after patterning using a condition sample of the sample B, and as shown in FIG. 14, it was found that although the surface side of the portion irradiated with the laser beams was resolved, the rear surface side of the resist was not resolved, and the resolution was remarkably deteriorated when compared with the resolution of the inorganic resist 4 with a single layer structure (FIG. 10 given in the embodiment 3).

As described above, it was found that when an oxide-based inorganic resist 4 was used and the oxygen concentration was varied in a gradient manner in the depth direction of the resist to thereby achieve the high resolution, it was difficult to achieve the high resolution only by increasing the oxygen concentration toward the rear surface side of the resist, and a proper material design was required based on a basic physical property of the inorganic resist 4 and a basic physical property of the substrate 1.

### 2. A Case that the Ground Layer and the Inorganic Resist are Provided on the Substrate

### Example 2

In this example, chromium oxide (CrOx)-based material with high etching durability was used instead of using tungsten oxide (WOx) as the material of the inorganic resist 4, and further the ground layer 2 is provided. Note that regarding a portion not specified in particular, the sample of this example is fabricated using the same technique as the technique of the example 1.

Specifically, the sample of this example was fabricated as follows.

The ground layer 2 made of silicon dioxide (SiO₂) was formed on a precisely polished stainless substrate 1 by CVD method in a thickness of 300 nm, and the inorganic resist 4 made of chromium suboxide with a compositional gradient structure was formed thereon in a thickness of 30 nm.

At this time, the thermal conductivity of the silicon dioxide (SiO₂) of the ground layer 2 was evaluated by laser heat reflection, and it was found that the thermal conductivity was 1.35 W/m·k.

Further, the value of x was continuously decreased in the depth direction of the resist, so that the oxygen amount (x), in a case that the material composition is defined as CrOx, was expressed by x=1.7 on the main surface side of the resist, and x=0.9 on the rear surface side of the resist (interface side of the quartz substrate 1), as a proper gradient composition of the inorganic resist 4 when using the stainless substrate 1 having the ground layer 2 formed thereon. Specifically, sputtering was applied from the rear surface side to the front surface side by continuously varying the oxygen gas ratio from about 15% to about 25%.

Here, the inorganic resist 4 was used as an etching mask, and SiO₂ was selected as the material of the ground layer 2, and therefore the specification of the substrate was formed like: chromium-based inorganic resist 4 with patterns (with a thickness of 20 nm)/SiO₂ ground layer 2 (with a thickness of 300 nm)/stainless substrate 1 (with a thickness of 1 mm) sequentially from the main surface side of the resist.

Next, drawing was carried out on the inorganic resist 4 using the same technique as the technique of example 1. Note that a proper range of the laser irradiation power was 12 to 20 mW, at the time of the laser irradiation under the condition described in the example 1.

Thereafter, similarly to the example 1, development, washing by pure water, and IPA vapor drying were carried out, and the pattern forming process applied to the resist was ended.

Further, dry etching process was carried out for transferring the fabricated resist pattern 5 to the ground layer 2. FIG. 6 shows the pattern forming process applied to the ground layer 2 based on the substrate specification.

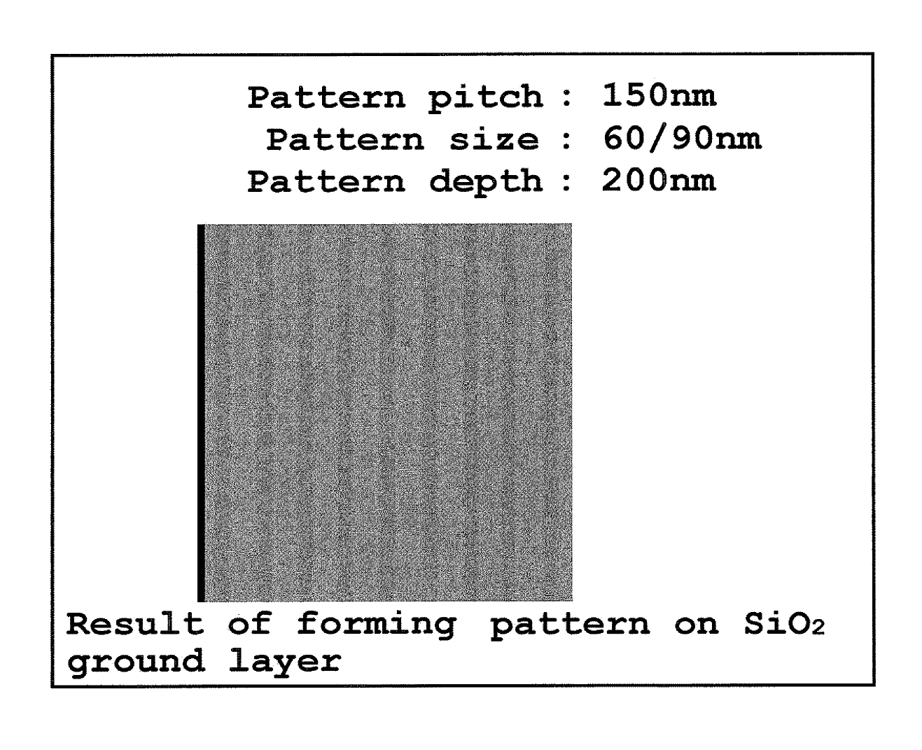

At this time, CF₄ was used as etching main gas, and oxygen was used as assist gas, in consideration of a dry etching characteristic of the resist material and the material of the ground layer 2. FIG. 15 shows a pattern observation result by SEM after dry etching process.

The etching durability of the chromium-based material against fluorine gas was sufficiently high, and an etching selection ratio of the SiO₂ ground layer 2 and the CrOx-based inorganic resist 4 was 10 or more, and anisotropic etching was enabled, with 200 nm or more pattern depth of the inorganic resist 4 with a thickness of 20 nm of the inorganic resist 4.

This case shows that a fine pattern of 100 nm or less is formed by blue semiconductor laser beams and its pattern can be easily transferred to the ground layer 2 by using the CrOx-based inorganic resist with high etching durability against the fluorine gas, and by optimizing the oxygen composition in the depth direction of the resist.

### 3. A Case that the Ground Layer, the Etching Mask Layer, and the Inorganic Resist are Provided on the Cylindrical Base Material

### Example 3

In this example, molybdenum oxide (MoOx)-based material was used instead of tungsten oxide (Wax) as the material of the inorganic resist 4, and the ground layer 2 was formed and the etching mask layer 3 was also formed thereon. Further, the cylindrical base material was used instead of the substrate 1.

Specifically, the sample of this example was fabricated as described below.

An amorphous carbon film was formed in a film thickness of 400 nm by CVD method on a precisely polished cylindrical base material made of aluminum alloy, and an oxynitride tantalum (TaOxNy) etching mask was formed on an upper layer thereof in a thickness of 15 nm. Further, the inorganic resist 4 made of molybdenum oxide was formed on the TaNx etching mask in a thickness of 15 nm.

At this time, the thermal conductivity of the amorphous carbon film of the ground layer 2 was evaluated by the laser heat reflection, and it was found that the thermal conductivity was 1.8 W/m·k. Further, the thermal conductivity of the oxynitride tantalum film of the etching mask layer 3 was evaluated similarly by the laser heat reflection, and it was found that the thermal conductivity was 2.1 W/m·k.

The value of x was continuously varied so that the oxygen amount (x) was expressed by x=3.1 on the main surface side of the resist, and x=1.6 on the rear surface side of the resist (interface side of the cylindrical base material) in a case of the material composition being MoOx, as the proper gradient composition of the inorganic resist 4 when using the aluminum cylindrical base material on which the ground layer 2 and the etching mask layer 3 were formed. Specifically, the inorganic resist was laminated while varying the oxygen gas ratio from about 25% to about 45%.

The specification of the substrate of this example was formed like: molybdenum oxide-based inorganic resist 4 (with a thickness of 15 nm)/oxynitride tantalum etching mask layer 3 (with a thickness of 15 nm)/amorphous carbon ground layer 2 (with a thickness of 400 nm)/cylindrical aluminum alloy base material 4 (100 mmφ, with a thickness of 10 mm).

Next, drawing was carried out on the inorganic resist 4 by the same technique as the technique of the example 1. Note that the drawing device of the example was selected as a laser drawing device with a specification responding to the cylindrical base material. Then, a proper range of the laser irradiation power was set to 16 to 24 mW upon irradiation of the laser beams under the condition described in the example 1.

Thereafter, after finishing the development, the substrate 1 was washed by pure water and dried by IPA vapor similarly to the example 1, to thereby end the pattern forming process.

Further, FIG. 7 shows a dry etching process carried out by a process device responding to the cylindrical base material for transferring the fabricated resist pattern 5 to the ground layer 2 through the etching mask layer 3. FIG. 7 is a schematic view showing a partially extracted cylindrical base material in a planar view.

In order to transfer the resist pattern 5 to the TaOxNy etching mask layer 3, chlorine (Cl₂) was used as the etching main gas, and oxygen (O₂) was used as the assist gas, to thereby carry out dry etching process.

Subsequently, after selectively removing the inorganic resist 4, etching process was applied to the amorphous carbon ground layer 2 using C₂F₆/O₂ gas and the TaOxNy etching mask, to obtain a pattern depth of 200 nm.

Finally, the already used etching mask layer 3 was removed and washed, to thereby fabricate a cylindrical roller mold with a fine pattern formed on the amorphous ground layer 2.

According to this method, the resist can be formed on a three-dimensional (3D) structure such as a cylindrical body, and a laser drawing on a rotary body is achieved. In addition, a method for forming a fine pattern in a large area is achieved, capable of fabricating a cylindrical roller mold for a roller nano-imprint, having a fine pattern of 100 nm or less thereon.

<Supplementary Description of Examination Contents by Inventors of the Present Invention>

A technical concept of the present invention is described above, and a history and further details of the examination contents to achieve the technical concept of the present invention will be additionally described hereafter.

The inventors of the present invention initially employ a method for varying only a degree of the thermal conduction (thermal conductivity) of the inorganic resist, for examining the aforementioned technique, and consider that the thermal conductivity on the main surface side of the resist is preferably increased from a viewpoint of transferring heat toward the rear surface side, when only the thermal conductivity of the inorganic resist is taken into consideration.

Meanwhile, it is also considered that the thermal conductivity on the rear surface side is preferably decreased from a viewpoint of allowing the temperature of the inorganic resist to reach a phase change temperature on the rear surface side of the resist.

Accordingly, it is also considered that in the WOx-based inorganic resist for example, if the oxygen concentration is increased toward the rear surface side, the sensitivity is also increased toward the rear surface side, and the rear surface side can also be resolved.

However, an expected effect of an experiment result can't be obtained, and rather a reversed result is obtained.

Regarding this point, patent document 4 describes as follows.

Namely, as a subject of the present invention, as the “distance from the surface of the inorganic resist becomes larger, the “thermal conductivity” becomes smaller, and as a result, a phase change reaction, namely, a variation rate of a variation from amorphous to crystal becomes small. Therefore, an insufficient development phenomenon occurs in a part where the variation rate is small, thus forming an incomplete state of a bottom surface such as pits and grooves, resulting in a smooth inclination angle, etc., of a wall surface of the pits and grooves”.

Note that the thermal conductivity is fixed in a single layer composed of a uniform material layer and a uniform density layer in any part of the layer. Therefore, according to this description, it may be appropriate to say that “as the distance from the surface of the inorganic resist becomes larger, “a heat conduction amount” becomes smaller”.

As the means for solving the problem, patent document 4 describes as follows.

“In this invention, irregularities are formed by irradiating an inorganic resist layer with laser beams, the inorganic resist layer being made of defective oxide of a transition metal, and by utilizing such a performance of the defective oxide such that the defective oxide is changed from an amorphous state to a crystal state when heat quantity by exposure exceeds a threshold value and is soluble in alkali.

Accordingly, there is a correspondence between the threshold value and the sensitivity. This means that a low threshold value corresponds to a high sensitivity. The sensitivity of the inorganic resist varies corresponding to the oxygen concentration (meaning oxygen content) in the inorganic resist layer. As the oxygen concentration is increased, the sensitivity becomes higher. The oxygen concentration varies in accordance with a film forming power and the ratio of a reactive gas during film formation by sputtering, etc., applied to the inorganic resist layer. Therefore, according to this invention, by utilizing such a variation of the oxygen concentration, the sensitivity of the inorganic resist is sequentially varied in one resist layer (specifically, “the oxygen concentration of the inorganic resist layer is varied in a thickness direction” as described in claim 1 of the patent document 4), to thereby solve the aforementioned problem.”

According to the patent document 4, “when the heat quantity by exposure exceeds the threshold value, the defective oxide is changed from the amorphous state to the crystal state”, and therefore the “threshold value” in the patent document 4 corresponds to the “phase change temperature from (the amorphous state to the crystal state)”.

Namely, in other words, the invention described in the patent document 4 utilizes the “phase change temperature” which is varied corresponding to the “oxygen concentration in the inorganic resist layer”.

As described above, according to the invention described in the patent document 4, “the sensitivity on the bottom surface side is increased”, namely “the threshold value on the bottom surface side is decreased (the phase change temperature on the bottom surface side is decreased)”, so that the phase change occurs even if the “the heat conduction amount” on the bottom surface side is small.

Meanwhile, the technique of “having anisotropy in the inorganic resist layer” of this embodiment, is a technique of obtaining a temperature distribution having anisotropy in the depth direction of the resist, when the resist is similarly irradiated with laser beams. This is different from the technique of “decreasing the phase change temperature on the bottom surface side” of the patent document 4.

For example, when the quartz substrate is used as the substrate, and the suboxide tungsten (WOx) is used as the resist, as described in this embodiment, it is found that highest heat absorption is observed at an oxygen composition allowing the resolution pattern size to become a maximum value, in a relation between a resolution pattern size drawn under a constant condition as shown in FIG. 3, and the oxygen composition in the WOx inorganic resist. Therefore, the rear surface side of the resist is preferably made of this composition at this time, and it is appropriate to form a gradient composition shown by arrow III in this figure, when using the quartz substrate and the WOx-based resist only.

Note that as described above, it appears that the first embodiment of the patent document 4 shows a resist composition shown by arrow I of FIG. 3. Further, it appears that the second embodiment of the patent document 4 shows a resist composition shown by arrow II of FIG. 3.

However, as described above, a resist pattern having an excellent pattern profile can't be formed as shown by arrow III of this embodiment.

Namely, the resolution of the resist can't be improved unless actions of the aforementioned optical-absorption coefficient and thermal conductivity are optimized.

As described above, a difference between this embodiment and the patent document 4 is summarized as follows.

In this embodiment, the degree of the resolution limit is increased by using a means for compensating the heat quantity when “the conduction amount of heat becomes small” from the main surface side to the rear surface side of the resist, specifically by using a means for increasing the anisotropy of the temperature distribution (for example, a technique of increasing the optical-absorption coefficient toward the rear surface side, decreasing the thermal conductivity toward the rear surface side, improving the resolution pattern characteristic (dimension) toward the rear surface side, and providing a well-balanced aforementioned three characteristics toward the rear surface side, from the main surface side of the resist).

Meanwhile, in the invention of the patent document 4, “the phase change is caused with a small heat quantity (low end-point temperature)” by “increasing the sensitivity on the bottom surface side”, namely by “decreasing the threshold value (phase change temperature) on the bottom surface side” so that the phase change is caused even if the “heat conducticin amount” on the bottom surface side is small. In other words, according to the invention described in the patent document 4, the resolution on the rear surface side is achieved by increasing the anisotropy of the threshold value (phase change temperature) toward the rear surface side. This is different from the invention included as a part of the present invention in which the anisotropy (heat conduction anisotropy) of the “the heat conduction amount” is increased.

Note that the invention described in the patent document 4 involves a problem that the resolution of the resist can't be sufficiently improved, for example, the resolution of a fine pattern of 100 nm or less is not achieved, because other function (such as optical-absorption coefficient) having most influence on the resolution of the resist is not taken into consideration, even if the resolution of the resist is considered to be optimized by focusing on only one of the functions such as thermal conductivity in the characteristics of the resist having a function of improving the resolution of the resist. Accordingly, in this embodiment, the degree of the influence on the resolution of the resist is examined in the characteristics of the resist having the function of improving the resolution of the resist, in accordance with a difference in materials and compositions. Then, based on the degree of the influence on the resolution of the resist thus obtained, one of the functions having most influence on the resolution of the resist is selected, and based on this function, the resolution of the resist is preferably maximized.

Further, the resolution of the resist can't be further improved, even if the resolution of the resist is considered to be optimized by focusing on the function having most influence on the resolution of the resist, for example, by focusing on the optical-absorption coefficient, in the characteristics of the resist having the function of improving the resolution of the resist, because other function (such as thermal conductivity) having an influence on the resolution of the resist, is not taken into consideration. For example, the resolution of the resist pattern of 50 nm level is not achieved in some cases. Accordingly, in this embodiment, preferably the degree of influence given to the resolution of the resist is examined in the characteristics of the resist having the function of improving the resolution of the resist, in accordance with the difference in materials and compositions, etc. Then, based on the degree of the influence on the resolution of the resist thus obtained, two or more functions having an influence on the resolution of the resist is selected, and based on these two or more functions, a plurality of functions are continuously varied in the depth direction of the resist, in a range of a relatively higher resolution (degree of resolution limit), and preferably in a range of a highest resolution (degree of resolution limit), to thereby continuously vary a plurality of functions in the depth direction of the resist and optimize (maximize) the resolution of the resist.

If comprehensively speaking, in order to improve the resolution of the resist, a relation between the “composition or density” of the resist material, and the “optical-absorption coefficient, thermal conductivity, and resolution pattern characteristics” is obtained (which is obtained as a graph for example), and an optimal gradient range of the “composition or density” can be determined, so as to optimize (preferably maximize) the resolution of the resist while considering the degree of the influence of the “optical-absorption coefficient, thermal conductivity, and sensitivity defined by the resolution pattern characteristic” given to the resolution.

Note that the material for optimizing the resolution of the resist is selected to obtain a temperature distribution having the anisotropy in the depth direction of the resist, when the resist is irradiated with laser beams. Specifically, the material is selected so that an area formed by isothermal lines in the resist is not formed into an isothermal shape with a laser irradiation point as a base point, but is formed into an anisotropic shape long in the depth direction (direction vertical to the substrate surface).

<Supplementary Description>

Preferred aspects of this embodiment will be described hereafter.

[Supplementary Description 1]

A method for forming a fine pattern, comprising:

Applying drawing or exposure to a substrate on which the functionally gradient inorganic resist is formed, by focused laser beams;

forming a portion changed in its state locally on the resist; and

causing a dissolution reaction to occur selectively by development.

[Supplementary Description 2]

A method for forming a fine pattern, comprising:

applying drawing or exposure to a substrate with resist including a ground layer made of a material different from the material of the functionally gradient inorganic resist, by focused laser beams;

forming a portion changed in its state locally on the resist;

forming a fine pattern on the resist by development; and

carrying out patterning to the ground layer by etching the ground layer using the fine pattern of the resist as a mask.

[Supplementary Description 3]

A method for forming a fine pattern, comprising:

applying drawing or exposure to a substrate by focused laser beams, using the substrate having an etching mask layer under the functionally gradient inorganic resist, and having a ground layer under the etching mask layer;

forming a portion changed in its state locally on the resist;

forming a fine pattern on the resist by development; and

transferring the fine pattern of the resist on the etching mask layer; and

carrying out patterning to the ground layer or the substrate by etching the ground layer or the substrate.

[Supplementary Description 4]

The method for forming a fine pattern, wherein patterning is carried out by combining the functionally gradient inorganic resist and focused laser beams with a wavelength range of 190 nm to 440 nm.

[Supplementary Description 5]

The method for forming a fine pattern, comprising:

forming a ground layer on a surface of a cylindrical base material;

forming a functionally gradient inorganic resist on the ground layer; and thereafter

selectively drawing or exposing and developing the resist by thermal lithography using focused laser beams having an automatic focusing function, to thereby carry out patterning of the resist into a desired shape;

transferring a pattern of the resist to the ground layer by etching; and

forming the ground layer having the pattern on the cylindrical base material.

[Supplementary Description 6]

The method for forming a fine pattern, wherein an already used functionally gradient inorganic resist layer is selectively removed after patterning the ground layer.

[Supplementary Description 7]

The method for forming a fine pattern, applied to a cylindrical base material or a three-dimensional structure, comprising:

carrying out patterning to a base material into a desired shape by selectively drawing or exposing and developing a resist layer on the base material, using the base material having an etching mask layer under the functionally gradient inorganic resist layer and having a ground layer under the etching mask layer as needed, and using focused laser beams having an automatic focusing function; and

transferring a pattern to the etching mask; and

carrying out patterning to the ground layer or the base material by etching.

[Supplementary Description 8]

The method for forming a functionally gradient inorganic resist, wherein the single layer resist is formed by reactive sputtering applied to a sputtering target composed of at least one or more elements of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, under an atmosphere of any one of oxygen, nitrogen, oxygen and nitrogen, oxygen and inert gas, oxygen and nitrogen and inert gas, and nitrogen and inert gas.

[Supplementary Description 9]

A functionally gradient inorganic resist having a main surface irradiated with laser beams, and a rear surface opposed to the main surface, and configured to change in its state by heat, comprising

a single layer resist including oxygen and/or nitrogen,

wherein a ratio of the oxygen and/or the nitrogen in the single layer resist becomes continuously smaller from the main surface side to the rear surface side, in a range of more than a composition ratio of the oxygen and/or the nitrogen at a point where a resist sensitivity shows a maximum value, in a relation between the composition ratio of the oxygen and/or the nitrogen and the resist sensitivity in the single layer resist, and

in the single layer resist, anisotropy of an area in which a temperature reaches a fixed temperature when irradiated with laser beams locally, is continuously increased from the main surface side to the rear surface side.

[Supplementary Description 10]

The functionally gradient resist having a main surface irradiated with laser beams, and a rear surface opposed to the main surface, and configured to change in its state by heat,

wherein the rear surface side of the functionally gradient inorganic resist has a composition of allowing a resist sensitivity to show a maximum value in a relation between a composition of the functionally gradient inorganic resist and the resist sensitivity, and

the composition of an arbitrary element of the functionally gradient inorganic resist is decreased from the main surface side to the rear surface side.

[Supplementary Description 11]

The functionally gradient inorganic resist including a single layer resist,

wherein the rear surface side of the single layer resist has a composition of allowing a resist sensitivity to show a maximum value in a relation between the composition of the single layer resist and a resist sensitivity, and

the composition of the single layer resist is continuously varied from the main surface side to the rear surface side.

[Supplementary Description 12]

The functionally gradient inorganic resist, wherein a range in which the composition of the single layer resist is continuously varied, is between the composition of allowing the resist sensitivity to have the maximum value, and the composition of allowing an optical-absorption coefficient to be continuously varied.

[Supplementary Description 13]

The functionally gradient inorganic resist, wherein a range in which the composition of the single layer resist is continuously varied, is within a range from the composition of allowing the resist sensitivity to have the maximum value, to the composition of allowing a thermal conductivity to be continuously varied.

[Supplementary Description 14]

The functionally gradient inorganic resist, wherein the single layer resist is made of a combination of at least one or more elements selected from Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and oxygen and/or nitrogen, and

a composition ratio of the oxygen and/or the nitrogen is continuously decreased from the main surface side to the rear surface side, in the composition ratio of the selected element and the oxygen and/or the nitrogen.

[Supplementary Description 15]

The functionally gradient inorganic resist,

wherein a material of the single layer resist is a substance expressed by WOx (0.4≦x≦2.0), wherein a value of x is continuously decreased from the main surface side to the rear surface side.

[Supplementary Description 16]

A method for forming a functionally gradient inorganic resist having a main surface irradiated with laser beams and a rear surface opposed to the main surface, and configured to change in its state by heat, comprising:

obtaining a composition of allowing a resist sensitivity to show a maximum value in a relation between the composition of the functionally gradient inorganic resist and the resist sensitivity;

starting film formation of the functionally gradient inorganic resist so that the rear surface side of the functionally gradient inorganic resist has a composition of allowing the resist sensitivity to have the maximum value; and

decreasing a composition of an arbitrary element of the functionally gradient inorganic resist from the main surface side to the rear surface side, by varying at least one of a gas partial pressure, a film forming rate, and a film forming output upon film formation, after starting the film formation.

[Supplementary Description 17]

A method for forming a functionally gradient inorganic resist, comprising:

obtaining a composition of allowing a resist sensitivity to show a maximum value in a relation between the composition of the single layer resist and the resist sensitivity;

starting film formation of the functionally gradient inorganic resist so that the resist sensitivity on the rear surface side of the single layer resist becomes the maximum value; and

continuously varying the composition of the single layer resist from the main surface side to the rear surface side by continuously varying at least one of the gas partial pressure, film forming rate, and film forming output upon film formation after starting the film formation,

when at least one single layer resist constituting the functionally gradient inorganic resist, is formed.

[Supplementary Description 18]

A method for forming a functionally gradient inorganic resist, for forming the functionally gradient inorganic resist on a ground layer made of a material different from the material of the single layer resist, comprising:

obtaining an optimal range for continuously varying the composition of the single layer resist, depending on the ground layer.

### DESCRIPTION OF SIGNS AND NUMERAL

1 Substrate
2 Ground layer
3 Etching mask
4 Functionally gradient inorganic resist
5 Resist pattern (concave portion)
101 Substrate
102 Inorganic resist
103 Resist pattern (concave portion)

1. A functionally gradient inorganic resist that changes in its state by heat, having:
a main surface irradiated with laser beams and a rear surface opposed to the main surface;
the functionally gradient inorganic resist including a single layer resist,
wherein at least a composition of the single layer resist is continuously varied from the main surface side to the rear surface side, and
anisotropy of an area in which a temperature reaches a fixed temperature when being irradiated with laser beams locally, is continuously increased from the main surface side to the rear surface side in the single layer resist.

2. A functionally gradient inorganic resist that changes in its state by heat, having:
a main surface irradiated with laser beams and a rear surface opposed to the main surface,
the functionally gradient inorganic resist including a single layer resist,
wherein in this single layer resist, a resist resolution characteristic value of the single layer resist is continuously varied from the main surface side to the rear surface side, and anisotropy of an area in which a temperature reaches a fixed temperature when being irradiated with laser beams locally, is continuously increased from the main surface side to the rear surface side,
wherein the resist resolution characteristic value is a physical value of a resist having an influence on a resolution of the resist.

3. A functionally gradient inorganic resist according to claim 2, wherein the resist resolution characteristic value is one or two or more values selected from optical-absorption coefficient, thermal conductivity, and resist sensitivity, wherein, the resist sensitivity is a characteristic defined by a dimension of a portion that can be developed when the resist is irradiated with laser beams having a prescribed dimension and irradiation amount.

4. A functionally gradient inorganic resist according to claim 1, wherein the single layer resist is made of a combination of at least one or more elements selected from Ti, V, Cr, Mn, Cu, Zn, Ge, Se, Y, Zr, Nb, Mo, Te, Ru, Rh, Pd, Ag, Sb, Te, Hf, Ta, W, Re, Ir, Pt, Au, and Bi, and oxygen and/or nitrogen, and a composition ratio of the selected element and oxygen and/or nitrogen is continuously varied from the main surface side to the rear surface side.

5. The functionally gradient inorganic resist according to claim 1, wherein the single layer resist is made of a first material composed of at least one of suboxide, nitride, or suboxynitride of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and a second material made of at least one of the above elements excluding the first material, wherein compositions of the first material and the second material are relatively and continuously varied from the main surface side to the rear surface side.

6. A functionally gradient inorganic resist of a single layer that changes in its state by heat, having:
a main surface irradiated with laser beams and a rear surface opposed to the main surface,
wherein the single layer resist is made of a combination of at least one or more elements selected from Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, and Bi, and oxygen and/or nitrogen, and
a composition ratio of the oxygen and/or the nitrogen with respect to the selected element is continuously small from the main surface side to the rear surface side in a range of a composition ratio or more of the oxygen and/or the nitrogen allowing a resist sensitivity to show a maximum value in a relation between the composition ratio of the oxygen and/or the nitrogen with respect to the selected element, and the resist sensitivity, and
anisotropy of an area in which a temperature reaches a fixed temperature when being irradiated with laser beams locally, is continuously increased from the main surface side to the rear surface side,
wherein the resist sensitivity is a characteristic defined by a dimension of a portion that can be developed when being irradiated with laser beams having a prescribed dimension and an irradiation amount.

7. A functionally gradient inorganic resist according to claim 6, wherein the material of the single layer resist is a substance expressed by WOₓ (0.4≦x≦2.0), and a value of x is continuously decreased from the main surface side to the rear surface side.

8. A functionally gradient inorganic resist according to claim 1, wherein a thickness of the single layer resist is in a range of 5 nm or more and less than 40 nm.

9. A functionally gradient inorganic resist according to claim 1, wherein the single layer resist has an amorphous structure in which optical characteristic and thermal characteristic are varied in a gradient manner from the main surface side to the rear surface side,
wherein, the optical characteristic includes optical-absorption coefficient, and is the characteristic caused by light, having an influence on the resolution of the resist, and the thermal characteristic includes thermal conductivity, and is the characteristic caused by light, having an influence on the resolution of the resist.

10. A substrate with functionally gradient inorganic resist according to claim 1, and a ground layer made of a material different from the material of the functionally gradient inorganic resist,
wherein the material of the ground layer is
(1) at least one or more of oxides, nitrides, carbides of Al, Si, Ti, Cr, Zr, Nb, Ni, Hf, Ta, and W, or a composite compound of them, or
(2) (i) at least one or more of amorphous carbon, diamond-like carbon, graphite comprising carbon, or carbide nitride comprising carbon and nitrogen, or
(ii) at least one or more of materials obtained by doping a carbon-containing material with fluorine.

11. The substrate with functionally gradient inorganic resist according to claim 10, wherein a thickness of the ground layer is in a range of 10 nm or more and less than 500 nm.

12. A substrate with a functionally gradient inorganic resist including an etching mask layer under the functionally gradient inorganic resist according to claim 1, and the ground layer under the etching mask layer,
wherein the material of the ground layer is
(1) at least one or more of oxides, nitrides, carbides of Al, Si, Ti, Cr, Zr, Nb, Ni, Hf, Ta, and W, or a composite compound of them, or
(2) (i) at least one or more of amorphous carbon, diamond-like carbon, graphite comprising carbon, or carbide nitride comprising carbon and nitrogen, or
(ii) at least one or more of materials obtained by doping a carbon-containing material with fluorine.

13. The substrate with a functionally gradient inorganic resist according to claim 12, wherein a thickness of the etching mask layer is in a range of 5 nm or more and less than 500 nm.

14. The substrate with a functionally gradient inorganic resist according to claim 10, wherein the substrate is mainly composed of metal, alloy, quartz glass, multi-component glass, crystal silicon, amorphous silicon, glasslike carbon, glassy carbon, and ceramics.

15. A cylindrical base material with a functionally gradient inorganic resist, wherein the cylindrical base material is used instead of the substrate of claim 10.

16. A method for forming a functionally gradient inorganic resist which changes in its state by heat
having a main surface irradiated with laser beams and a rear surface opposed to the main surface,
wherein at least one single layer resist constituting the resist is composed of a combination of at least one or more elements of Ti, V, Cr, Mn, Cu, Zn, Ge, Se, Y, Zr, Nb, Mo, Tc, Ru, Rh, Pd, Ag, Sb, Te, Hf, Ta, W, Re, Ir, Pt, Au, Bi, and oxygen and/or nitrogen,
wherein at least a composition of the single layer resist is continuously varied from the main surface side to the rear surface side, by continuously varying at least one of gas partial pressure, film forming rate, and film forming output for forming the single layer resist.

17. A method for forming a fine pattern, comprising:
applying drawing or exposure to a substrate on which the functionally gradient inorganic resist of claim 1 is formed, by focused laser beams;
forming a portion that changes in its state locally on the resist; and
causing selective dissolution to occur by development.

18. An inorganic resist that changes in its state, having:
a main surface irradiated with laser beams and a rear surface opposed to the main surface,
wherein the rear surface side of the inorganic resist has a composition allowing a resist sensitivity to show a maximum value in a relation between a composition of the inorganic resist and the resist sensitivity.

19. A method for forming an inorganic resist that changes in its state, having a main surface irradiated with laser beams and a rear surface opposed to the main surface,
the method comprising:
obtaining a composition allowing a resist sensitivity to show a maximum value in a relation between a composition of the inorganic resist and the resist sensitivity; and
forming an inorganic resist so that the rear surface side of the inorganic resist has a composition allowing the resist sensitivity to show the maximum value.
